(19) United States
(12) Patent Application Publication
(10) Pub. No.: US 2026/0113943 A1
(43) Pub. Date: Apr. 23, 2026

(54) P-TYPE AND N-TYPE DOPING OF A BACKSIDE SOURCE FOR MEMORY CHANNELS

(71) Applicant: Micron Technology, Inc., Boise, ID (US)

(72) Inventors: Masaaki Higuchi, Yokohama (JP); Jun Fujiki, Boise, ID (US); Yoshiaki Fukuzumi, Yokohama (JP); Kenichiro Nakagawa, Kawasaki (JP)

(21) Appl. No.: 19/332,154

(22) Filed: Sep. 18, 2025

Related U.S. Application Data
(60) Provisional application No. 63/708,274, filed on Oct. 17, 2024.

(51) Int. Cl. H10B 43/27; H10B 41/27; H10B 41/35; H10B 43/35; H10D 30/01; H10D 30/68; H10D 30/69

(52) U.S. Cl. CPC H10B 43/27; H10B 41/27; H10B 41/35; H10B 43/35; H10D 30/0411; H10D 30/0413; H10D 30/689; H10D 30/693

(57) ABSTRACT

Methods, systems, and devices for p-type and n-type doping of a backside source for memory channels within an apparatus are described. An apparatus may be formed with both an n-type doped region and a p-type doped region coupled with a backside source. The two doped regions may support current generation for both erase and program operations, providing for reliable and efficient memory access operations. The doped regions may be separated from one another by the plug that protects the memory cells and other regions of the apparatus from diffusion during a backside source formation process. That is, the conductive plug may be formed and may be doped with opposite charges on opposite ends of the conductive plug before a backside source is subsequently formed and coupled with the two doped regions. The opposite ends of the conductive plug may be doped with opposite charges.

### CROSS REFERENCE

The present Application for Patent claims priority to U.S. patent application Ser. No. 63/708,274 by Higuchi et al., entitled “P-TYPE AND N-TYPE DOPING OF A BACKSIDE SOURCE FOR MEMORY CHANNELS,” filed Oct. 17, 2024 which is assigned to the assignee hereof, and which is expressly incorporated by reference in its entirety herein.

### TECHNICAL FIELD

The following relates to one or more systems for memory, including an apparatus including p-type and n-type doping of a backside source for memory channels.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system, including an apparatus, that supports formation of the apparatus including p-type and n-type doping of a backside source for memory channels in accordance with examples as disclosed herein.

FIGS. 2A through 2I show examples of memory architectures that support formation of an apparatus including p-type and n-type doping of a backside source for memory channels in accordance with examples as disclosed herein.

FIGS. 3A through 3J show examples of memory architectures that support formation of an apparatus including p-type and n-type doping of a backside source for memory channels in accordance with examples as disclosed herein.

FIGS. 4A through 4C show examples of memory architectures that support formation of an apparatus including p-type and n-type doping of a backside source for memory channels in accordance with examples as disclosed herein.

FIG. 5 shows an example of a memory architecture that supports formation of an apparatus including p-type and n-type doping of a backside source for memory channels in accordance with examples as disclosed herein.

FIG. 6 shows an example of a memory architecture that supports formation of an apparatus including p-type and n-type doping of a backside source for memory channels in accordance with examples as disclosed herein.

FIGS. 7A through 7C show examples of memory architectures that support formation of an apparatus including p-type and n-type doping of a backside source for memory channels in accordance with examples as disclosed herein.

FIGS. 8A and 8B show examples of memory architectures that support formation of an apparatus including p-type and n-type doping of a backside source for memory channels in accordance with examples as disclosed herein.

FIGS. 9A and 9B show examples of memory architectures that support formation of an apparatus including p-type and n-type doping of a backside source for memory channels in accordance with examples as disclosed herein.

FIG. 10 shows an example of a memory architecture that supports formation of an apparatus including p-type and n-type doping of a backside source for memory channels in accordance with examples as disclosed herein.

FIG. 11 shows an example of a memory architecture that supports formation of an apparatus including p-type and n-type doping of a backside source for memory channels in accordance with examples as disclosed herein.

FIG. 12 shows a flowchart illustrating a method or methods that support formation of an apparatus including p-type and n-type doping of a backside source for memory channels in accordance with examples as disclosed herein.

### DETAILED DESCRIPTION

Some memory systems (e.g., apparatuses) include vertical memory cells (e.g., vertical planar cell (VPC)), in which three-dimensional cell transistors (e.g., NAND memory cells) may be connected within a trench-like structure, or a pillar-like structure, for example (e.g., a vertical alignment between memory cells), to form a more scaled memory array than some other arrays in which some other structure may be used for memory cells. For example, a vertical memory cell may include a vertical cell channel that extends through multiple other vertical cells as well as a select gate. Each of the vertical memory cells may include a vertical portion that extends vertically along with the vertical memory storage node (e.g., string). A plug (e.g., a choking region) may be formed to protect areas within the apparatus from diffusion during a backside source formation process, in which a source may be formed for one or more of the memory cells by flipping the apparatus over, and depositing source materials from the “back side” of the apparatus (e.g., by removing the substrate or through the substrate using, for example, oxide-nitride-oxide (ONO) etching and poly diffusion). The source may be an n-type source (e.g., a semiconductor material doped with a material to generate an excess of negatively charged electrons). The source may be activated to generate a current within the cell transistors (e.g., a memory channel connecting multiple memory cells). However, using an n-type source material for current generation for multiple types of access operations (e.g., both erase and program operations) may not be reliable. Thus, generation of, and spacing between, two different types of doped regions within or otherwise coupled with the source may be beneficial.

Techniques, apparatuses, systems, and devices described herein provide for generation of both an n-type doped region and a p-type doped region (e.g., a semiconductor material doped with a material to generate an excess of positively charged electrons) coupled with or otherwise included in a backside source. The two doped regions may support current generation for both erase and program operations, providing for reliable and efficient memory access operations within a three dimensional memory system. The doped regions may be separated from one another by the plug that protects the memory cells and other regions of the memory system from diffusion during a backside source formation process. That is, the conductive plug may be formed and may be doped with opposite charges on opposite ends of the conductive plug before a backside source is subsequently formed and coupled with the two doped regions. The opposite ends of the conductive plug may be doped with opposite charges, and a middle region of the plug may remain undoped (e.g., neutral).

The plug may extend in a horizontal direction beneath multiple memory cell channels that extend vertically through at least a portion of the stack. In some examples, the plug may be longer in a first horizontal direction than the plug is wide in a second horizontal direction. For example, the plug may be a rectangular prism, among other examples. The two doped regions may be on opposite sides of the plug in either the first direction or the second direction. In some examples, the two doped regions may be on each end of the plug length-wise, such that the two doped regions are relatively far apart. Alternatively, the two doped regions may be on each end of the plug width-wise, such that the two doped regions are relatively closer to each other, and may extend underneath all of the memory cell channels. In some examples, there may be more than one doped region included in or otherwise coupled with the plug. The described doping techniques may apply to different three-dimensional cell structures, including vertical cells, or other types of cell structures.

In addition to applicability in memory systems as described herein, techniques for formation of an apparatus including p-type and n-type doping of a backside source for memory channels may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory access speeds during both program and erase access operations, which may decrease processing and latency and may improve response times and user experience, among other benefits.

In addition to applicability in memory systems described herein, techniques for formation of an apparatus including p-type and n-type doping of a backside source for memory channels may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by improving cell density and formation of three-dimensional memory arrays with reduced materials while improving reliability of access operations, and may prevent or mitigate unauthorized access to data or other information, incur lower latency costs (e.g., by implementing it at hardware level) and use less power relative to other solutions, among other benefits.

Features of the disclosure are illustrated and described in the context of systems, apparatuses, devices, and circuits. Features of the disclosure are further illustrated and described in the context of memory architectures and flowcharts.

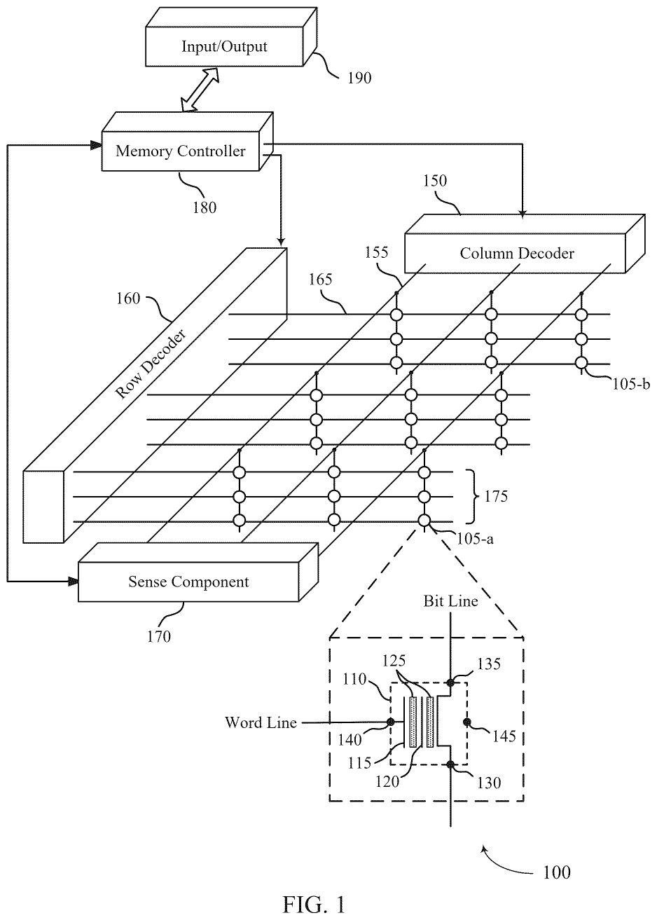

FIG. 1 shows an example of an apparatus 100 that supports p-type and n-type doping of a backside source for memory channels in accordance with examples as disclosed herein. FIG. 1 is an illustrative representation of various components and features of the apparatus 100. As such, the components and features of the apparatus 100 are shown to illustrate functional interrelationships, and not necessarily physical positions within the apparatus 100. Further, although some elements included in FIG. 1 are labeled with a numeric indicator, some other corresponding elements are not labeled, even though they are the same or would be understood to be similar, in an effort to increase visibility and clarity of the depicted features.

The apparatus 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

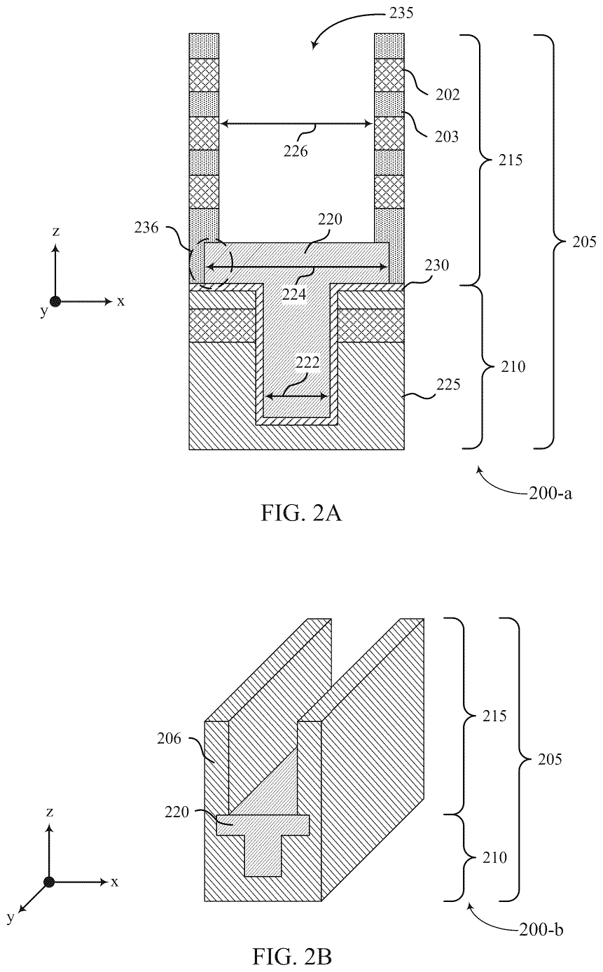

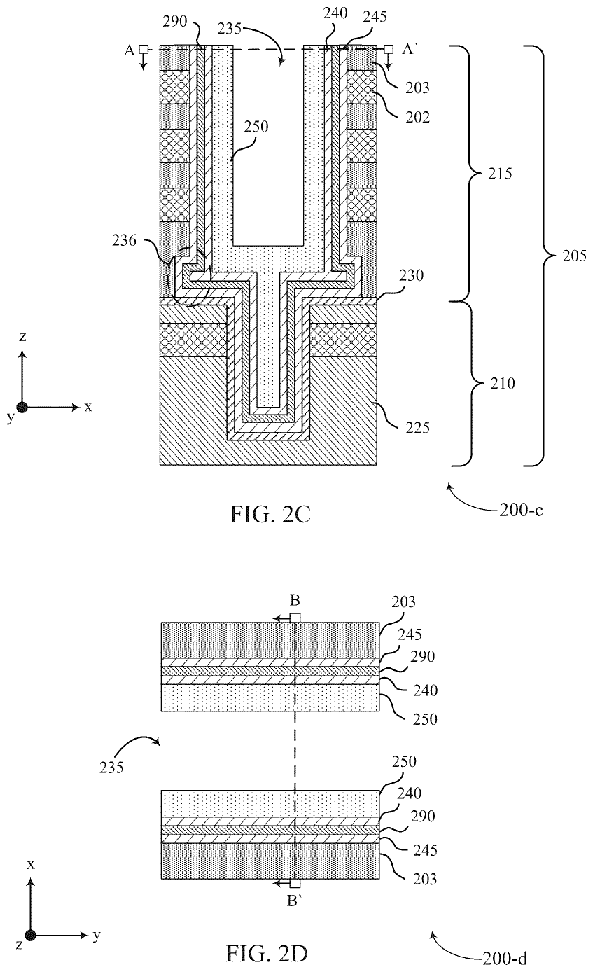

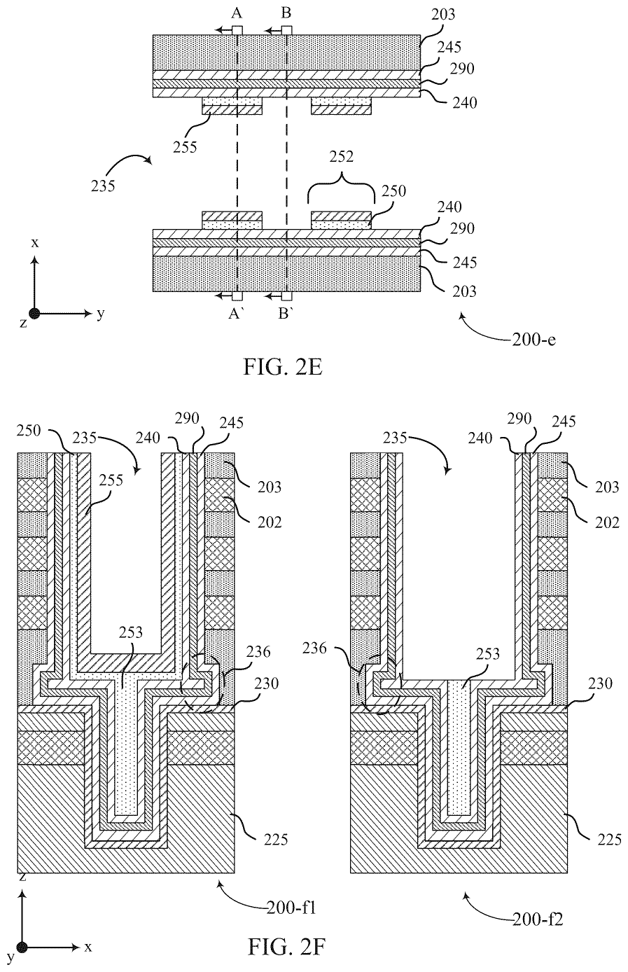

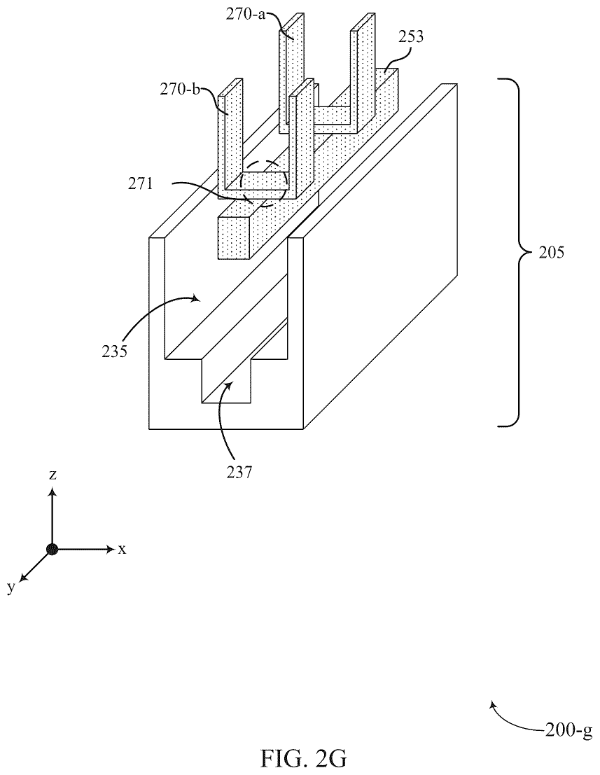

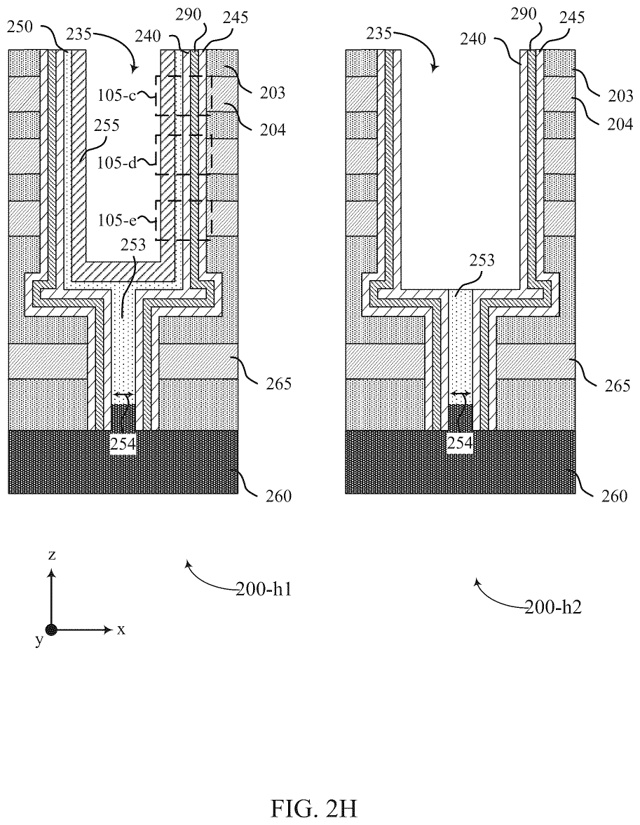

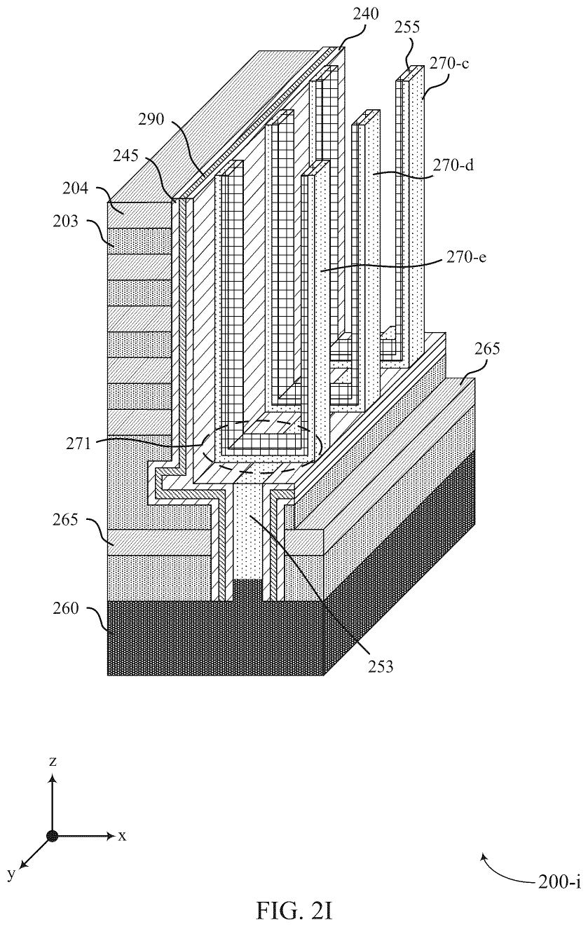

In some cases, an apparatus 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, apparatus 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIGS. 2A through 2I).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of apparatus 100.

The apparatus 100 (e.g., a memory system) may include vertical memory cells (e.g., VPCs), in which three-dimensional cell transistors (e.g., NAND memory cells) may be connected within a trench-like structure, or a pillar-like structure, for example (e.g., vertical alignment between memory cells), to form a more scaled memory array. For example, a vertical memory cell may include a vertical cell channel that extends through multiple other vertical memory cells as well as a select gate. Each of the vertical memory cells may include a vertical portion that extends vertically along with the vertical memory storage node (e.g., string). A plug (e.g., a choking region) may be formed to protect areas within the apparatus 100 from diffusion during a backside source formation process, in which a source may be formed for one or more of the memory cells by flipping the apparatus over, and depositing source materials from the “back side” of the apparatus (e.g., by removing the substrate or through the substrate using, for example, ONO etching and poly diffusion). The source may be an n-type source (e.g., a semiconductor material doped with a material to generate an excess of negatively charged electrons). The source may be activated to generate a current within the cell transistors (e.g., a memory channel connecting multiple memory cells 105). However, using an n-type source material for current generation for multiple types of access operations (e.g., both erase and program operations) may not be reliable. Thus, generation of, and spacing between, two different types of doped regions within or otherwise coupled with the source may be beneficial.

Techniques, apparatuses, systems, and devices described herein provide for generation of both an n-type doped region and a p-type doped region (e.g., a semiconductor material doped with a material to generate an excess of positively charged electrons) coupled with or otherwise included in a backside source. The two doped regions may support current generation for both erase and program operations, providing for reliable and efficient memory access operations within a three dimensional memory system. The doped regions may be separated from one another by the plug that protects the memory cells and other regions of the memory system from diffusion during a backside source formation process. That is, the conductive plug may be formed and may be doped with opposite charges on opposite ends of the conductive plug before a backside source is subsequently formed and coupled with the two doped regions. The opposite ends of the conductive plug may be doped with opposite charges, and a middle region of the plug may remain undoped (e.g., neutral).

The plug may extend in a horizontal direction beneath multiple memory cell channels that extend vertically through at least a portion of the stack. In some examples, the plug may be longer in a first horizontal direction than the plug is wide in a second horizontal direction. For example, the plug may be a rectangular prism, among other examples. The two doped regions may be on opposite sides of the plug in either the first direction or the second direction. In some examples, the two doped regions may be on each end of the plug length-wise, such that the two doped regions are relatively far apart. Alternatively, the two doped regions may be on each end of the plug width-wise, such that the two doped regions are relatively closer to each other, and may extend underneath all of the memory cell channels. In some examples, there may be more than one doped region included in or otherwise coupled with the plug.

FIGS. 2A through 2I show examples of memory architectures 200 after various processing steps that support formation of an apparatus including p-type and n-type doping of a backside source for memory channels accordance with examples as disclosed herein. The memory architecture 200 may be an example of a portion of an apparatus, such as an apparatus 100. FIGS. 2A through 2I show various views (e.g., diagonal or trimetric views, planar views, other views) of a memory architecture 200, which may be an example of a memory architecture implemented by an apparatus 100, as described with reference to FIG. 1. The memory architectures 200 may illustrate operations associated with forming an apparatus including memory cells across one or more levels of the apparatus that are connected with respective bit lines. Performing the processing steps may consolidate processing steps otherwise associated with forming a memory architecture. For example, the processing steps may support reduced diffusion of a source material to unnecessary regions of an apparatus, among other advantages.

For illustrative purposes, aspects of the memory architecture may be described with reference to an x-direction, a y-direction, and a z-direction of the illustrated coordinate systems. For example, memory architectures 200-b, 200-g, and 200-i illustrate the memory architecture from trimetric views, where a substrate of the memory architecture may be associated with an xy-plane, and where the memory architecture extends a distance along the z-direction. Additionally, the memory architectures 200-a, 200-c, 200-d, 200-e, 200-f1, 200-f2, 200-h1, and 200-h2, may illustrate the memory architecture with a cross-sectional and/or planar view, such that a portion of the memory architecture may be removed from the trimetric view to illustrate a cross-section of the memory architecture in the xz-plane, the xy-plane, or both. Although the memory architectures 200 illustrate examples of relative dimensions and quantities of various features, aspects of the memory architectures 200 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 2A through 2I may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, processing steps performed by such a manufacturing system may be supported by one or more controllers, such as one or more processors or processing circuitry, or its components as described herein.

FIG. 2A illustrates an example of a memory architecture 200-a after a first processing step associated with forming a stack of materials 205 and a sacrificial plug 220. For example, forming the stack of materials 205 may include depositing alternating (e.g., or at least partially alternating) layers of an oxide material 203 and a sacrificial material 202 above a substrate (e.g., a plane or sheet in the xy-plane on which subsequent memory materials may be formed. The substrate may be associated with complementary metal-oxide semiconductor (CMOS) circuitry. In some such examples, depositing the alternating layers may include depositing a layer of the oxide material 203, then depositing a layer of the sacrificial material 202 above the layer of the oxide material 203. Accordingly, the sacrificial material 202 and the oxide material 203 may be similarly deposited to form alternating layers, where the height of the stack of materials 205 may be based on the quantity and height of each of the alternating layers. In some implementations, the oxide material 203 may be a dielectric material, such as silicon oxide, silicon oxycarbide, silicon oxynitride, or silicon nitride. In some implementations, the sacrificial material 202 may be a variation of nitride.

In some examples, the stack of materials 205 may be formed in two or more formation processes. For example, the first level 210 may be formed first, and the second level 215 may be formed after formation of the first level 210. Forming the first level 210 may include depositing one or more layers of an oxide material 225 and one or more layers of the sacrificial material 302. The oxide material 225 may be the same as or different from the oxide material 303 in the second level 315. In some examples, after the first level 210 is formed, the first level 210 may be etched to form a first cavity (not pictured in FIG. 2A) having a first width 222. The first cavity may pass through the first level 210 of the stack of materials 205 in a first direction (e.g., vertical, the z-direction) and a second direction (e.g., horizontal, the y-direction), having a width 222 in a third direction (e.g., the x-direction). The first cavity may not extend fully through the first level 210, such that a portion of oxide material 225 may remain between the first cavity and a substrate, in some examples. The first cavity may be filled with a sacrificial material 230, which may be an oxide material, such as the oxide material 203, or some other material. The second level 215 may then be formed on top of the first level 210 including the cavity filled with the sacrificial material 230. In some examples, as illustrated in FIG. 2A, the sacrificial material 230 may form a liner between the first level 210 and a first layer of oxide material 203 in the second level 215.

After forming the second level 215 of the stack of materials 205, one or more other cavities may be formed. For example, a second cavity 235 may be formed in the second level 215 of the stack of materials 205. The second cavity 235 may be above the first cavity relative to the substrate. The second cavity 235 may pass through the second level 215 of the stack of materials 205 in the first direction (e.g., the z-direction) and the second direction (e.g., the y-direction). The first cavity and the second cavity 235 may be formed via respective etch processes in which materials are removed from the stack of materials 205 to form the cavities. The first cavity may be formed with a first width 222 and the second cavity 235 may be formed with a second width 226, where the second width 226 is greater than the first width 222.

In some examples, a recess 236 may be formed within the stack of materials 205 between the first cavity and the second cavity 235. For example, a portion of a first layer of oxide material 203 in the second level 215 of the stack of materials 205 may be etched to form a recess 236 (e.g., on each side of the stack) that expands a width of the second cavity 235 from the second width 226 to a third width 224 that is greater than the first width 222 and the second width 226.

After forming the stack of materials 205 and the various cavities, a sacrificial plug 220 may be formed within the first cavity and the recess 236. For example, a sacrificial plug material may be deposited within the first cavity and the recess 236 to form the sacrificial plug 220. In some examples, the formation of the sacrificial plug 220 may form the recess 236 (e.g., the sacrificial plug material may etch back or recede a portion of the oxide material 203). Additionally, or alternatively, the sacrificial plug 220 may be formed within the first cavity before formation of the second level 215, and the second level 215 may be formed on top of the sacrificial plug 220. The sacrificial plug 220 may be a T-shaped plug, or some other shape having the first width 222 in the first level 210 of the stack and the third width 224 in the second level 215 of the stack.

FIG. 2B illustrates an example of a memory architecture 200-b after the first processing step associated with forming the sacrificial plug 220 within the stack of materials 205. For example, the memory architecture 200-b illustrates a trimetric view (e.g., a diagonal view) of the stack of materials 205 illustrated in FIG. 2A. For clarity, some features of the stack of materials 205 are not illustrated in FIG. 2B. For example, the material 206 may be a simplified representation of the alternating layers of materials, including the oxide material 203 and the sacrificial material 202, as described with reference to FIG. 2A.

As illustrated in FIG. 2B, after the sacrificial plug 220 is formed, the stack of materials 205 may represent a trench-shape, where the sacrificial plug 220 may be a T-shape that extends horizontally (e.g., in the y-direction) through the stack of materials 205 and further extends vertically (e.g., in the z-direction) in a portion of the first level 210 and a portion of the second level 215.

FIG. 2C illustrates an example of a memory architecture 200-c after a second processing step associated with forming various layers of materials within the stack of materials 205. For example, the sacrificial plug 220 may be removed (e.g., etched, exhumed) from the stack of materials 205, and one or more layers of materials may be deposited or formed within the first cavity, the recess 236, and the second cavity 235 after the sacrificial plug 220 is removed. The layers of materials may include, for example, a first protective liner 245, a storage material 290, and a second protective liner 240. The materials may be deposited and subsequently etched back to form liners that extend along sidewalls of the stack of materials 205. For example, the first protective liner 245 may extend along sidewalls of the stack of materials 205 within the first cavity, within the recess 236, and within the second cavity 235. The storage material 290 may extend along the first protective liner 245 and between the first protective liner 245 and the second protective liner 240. In some examples, the second protective liner 240 may be deposited and subsequently etched such that a shape of the second protective liner 240 may generally be a U-shape within the second level 215. That is, the second protective liner 240 may include, in some examples, fewer or no curves within the recess 236 than the first protective liner 245 and/or the storage material 290.

After the first protective liner 245, the storage material 290, and the second protective liner 240 are formed, a conductive material 250 may be formed (e.g., deposited) over the second protective liner 240 within a remainder of the first cavity and a portion of the second cavity 235. The conductive material 250 may be associated with one or more bit line structures of the apparatus. A size of the second cavity 235 after these depositions of materials may be reduced as compared with the size of the second cavity 235 in FIG. 2A. The conductive material 250 may thereby fill the first cavity, such that the first level 210 is filled with materials. The conductive material 250 may, in some examples, be formed in the shape of a football field goal post, or a rectangular U-shape connected to a vertical post.

FIG. 2D illustrates an example of a memory architecture 200-d after the second processing step described with reference to FIG. 2C. For example, FIG. 2D illustrates the stack of materials 205 from a birds-eye view (e.g., in the xy-plane). The memory architecture 200-d shown in FIG. 2D illustrates a cross-sectional view of the memory architecture 200-c shown in FIG. 2C, as cut across the A-A′ cross-sectional line. The memory architecture 200-c shown in FIG. 2C illustrates a cross-sectional view of the memory architecture 200-d shown in FIG. 2D, as cut across the B-B′ cross-sectional line.

As shown in FIG. 2D, after the various materials are formed, a top layer of the apparatus may include two sets of material segments. Each set of material segments including the oxide material 203, the first protective liner 245, the storage material 290, the second protective liner 240, and the conductive material 250. The two sets of materials may be sandwiched together with a space (e.g., the second cavity 235) in between the two sets of materials.

Although not pictured in FIG. 2D, it is to be understood that the second cavity 235 may extend some distance into the page in the z-direction, and there may be more conductive material 250 after the distance, as illustrated in FIG. 2C.

FIG. 2E illustrates an example of a memory architecture 200-e after a third processing step associated with etching back the conductive material 250. The memory architecture 200-e illustrates a birds-eye view of the stack of materials 205 (e.g., in the xy-plane).

The third processing step may include, for example, depositing a channel oxide material 255 within the second cavity 235. The channel oxide material 255 may be formed on top of the conductive material 250 and may be formed with a threshold thickness or may be etched back, such that the channel oxide material 255 has a relatively constant thickness within the second cavity 235. In some examples, the formation of the channel oxide material 255 may reduce a thickness of the conductive material 250 within the second cavity 235, as illustrated in FIG. 2E.

The third processing step may further include etching the conductive material 250 and the channel oxide material 255. The etching may be performed using a mask, which may cover some portions of the stack of materials and expose other portions. The conductive material 250 and the channel oxide material 255 within the exposed portions may be removed (e.g., etched, exhumed, or the like). There may be remaining segments 252 of conductive material 250 within the second cavity 235 (e.g., a trench). The conductive material 250 may be etched such that each segment 252 of conductive material is separated from (e.g., not in direct physical contact with) any other segment 252 of the conductive material within the second level 215 of the stack. The channel oxide material 255 may be etched to a similar or the same shape as the conductive material 250. In some examples, the channel oxide material 255 may be formed on top of the conductive material 250 after the etching. Additionally, or alternatively, the channel oxide material 255 may be formed prior to the etching.

FIG. 2F illustrates an example of memory architectures 200-f1 and 200-f2 after the third processing step described with reference to FIG. 2E. The memory architectures 200-f1 and 200-f2 represent an example of the memory architecture 200-e illustrated in FIG. 2E, but from a horizontal view (e.g., in the xz-plane). The memory architecture 200-f1 represents a cross sectional view of the memory architecture 200-e when cut across the A-A′ cross-sectional line. The memory architecture 200-f2 represents a cross sectional view of the memory architecture 200-e when cut across the B-B′ cross-sectional line.

When cut across the A-A′ cross-sectional line, the memory architecture 200-f1 may include each of the first protective liner 245, the storage material 290, and the second protective liner 240 extending along sidewalls of the stack of materials 205. The memory architecture 200-f1 may further include the conductive material 250 within the first level 210 and the second level 215 (e.g., within the second cavity 235). The channel oxide material 255 may further be included within the A-A′ cross-sectional view as a U-shape on top of the conductive material 250 in the second cavity 235. The conductive material 250 within the first level 210 of the stack may be referred to as a plug 253 herein. For example, the plug 253 may include all of the conductive material 250 that extends continuously in the y direction through the stack of materials 205 (e.g., to form a trench-shape). The conductive material 250 that extends from the plug 253 vertically within the second level 215 may be referred to as the segments 252. Thus, when the memory architecture 200-e illustrated in FIG. 2E is cut across the areas that include the segments 252, the conductive material 250 and the channel oxide material 255 are present within the second cavity 235.

However, when cut across the B-B′ cross-sectional line, the view of the memory architecture 200-f2 may not include the channel oxide material 255 and may not include the conductive material 250 along the sidewalls of the second cavity 235. For example, because of the etching performed in the third processing step, the conductive material 250 may be formed in U-shaped segments (e.g., rectangular U-shaped segments) within the second cavity 235, where the segments 252 extend from the plug 253 horizontally (e.g., in the x-direction) to a sidewall of the second cavity 235 (e.g., to the second protective liner 240), and then vertically (e.g., in the z-direction) along the sidewall of the second cavity 235 (e.g., along the second protective liner 240). The segments 252 may not, however, extend continuously in the x-direction. Instead, the segments 252 may have a threshold thickness in the x-direction due to the etching. In between the segments 252 may be some other insulating material or an absence of material (e.g., air), at least for part of the manufacturing process. As such, the cross-sectional view of the B-B′ cross-section may not include any conductive material 250 extending from the plug 253, and may instead include the plug 253 that terminates at the second cavity 235.

FIG. 2G illustrates an example of a memory architecture 200-g in accordance with an abstracted trimetric view after the third processing step described herein. The memory architecture 200-g is abstracted to improve clarity and highlight the shape of the plug 253 and corresponding memory channels 270 (e.g., memory channels 270-a and 270-b), each of which may include the conductive material 250 described with reference to FIGS. 2A through 2F. The plug 253 and the memory channels 270 (e.g., also referred to herein as bit line structures) may be removed from the stack of materials 205 for illustration purposes only, and it is to be understood that the plug 253 may be within the first cavity 237 and the memory channels 270 may be within the second cavity 235, as described and illustrated with reference to FIGS. 2A through 2F.

As illustrated in FIG. 2G, the plug 253 may be a rectangular or cubic shape that extends in the y-direction (e.g., horizontally) within a trench formed by the first cavity 237 in the first level of the stack of materials 205. The plug 253 may have a first thickness in the x-direction and a second thickness in the z-direction, where the first and second thicknesses may be the same or different. The plug 253 may provide a continuous and solid base connection point for each of the memory channels 270, which may protect against a source material being diffused throughout the memory architecture 200-g. The memory channels 270 may be in direct physical contact with the plug 253 at a base contact region 271, and may otherwise be separated from one another. For example, the memory channel 270-a may not be in direct physical contact with the memory channel 270-b. There may be an absence of material or some insulating material between the two memory channels 270-a and 270-b in the y-direction. The memory channels 270 may each extend horizontally in the x-direction from the base contact region 271 to sidewalls of the second cavity 235 and may extend vertically in the z-direction within the stack of materials 205 and along sidewalls of the second cavity 235. A memory channel 270 may be a channel of conductive material that extends between one or more memory cell transistors. The memory channels 270 may represent examples of conductive lines (e.g., strings) of memory cells 105 coupled between two selectors. For example, the memory channels 270 may represent a conductive channel between memory cells 105, which may be referred to as a memory channel herein. A bit line may be coupled with a top portion of the memory channels 270 via a selector, such as a select gate drain selector, a select gate source selector, or some other type of selector. In some examples, a connection between the memory channels 270 and the plug 253 may be referred to as a selector (e.g., a source side selector, among other examples) and may include a first portion. Each memory channel 270 may include a first string including a first selector with a first portion and a second string including a second selector with a second portion, where the first and second selectors are coupled with the plug 253.

FIG. 2H illustrates an example of memory architectures 200-h1 and 200-h2 after a fourth processing step associated with metallization and backside source formation. The memory architectures 200-h1 and 200-h2 represent an example of the memory architecture 200-e illustrated in FIG. 2E, but from a horizontal view (e.g., in the xz-plane). The memory architecture 200-h1 represents a cross sectional view of the memory architecture 200-e when cut across the A-A′ cross-sectional line. The memory architecture 200-h2 represents a cross sectional view of the memory architecture 200-e when cut across the B-B′ cross-sectional line.

As part of the fourth processing step, a metallization process may be performed to convert the sacrificial material 202 to the metal material 204. The stack of materials may thereby include layers of the oxide material 203 and layers of the metal material 204. The metallization may not alter the structure of the first protective liner 245, the second protective liner 240, the storage material 290, the plug 253, the conductive material 250, or the channel oxide material 255. The plug 253 may have a thickness 254.

The fourth processing step may further include a backside source formation process, in which the source 260 is formed. In some examples, a substrate may be positioned beneath the memory architectures 200-f1 and 200-f2 illustrated in FIG. 2F. As part of the backside source formation, the apparatus may be flipped or otherwise rotated and the substrate may be removed such that the manufacturing system may access a “backside” of the apparatus, which may correspond to a bottom of the first level 210 of the stack of materials 205.

A source material may be deposited from the backside of the apparatus to form the source 260. The source material may include an n+ poly-silicon material, some other material, or any combination thereof. The source material deposition may, in some examples, result in phosphorous diffusion, which may degrade a portion of the plug 253 (e.g., in the vertical or z-direction), but may not degrade or otherwise remove all of the plug 253 due to the plug 253 having sufficient thickness 254. As such, the plug 253 may remain during the backside source formation and the source 260 may be in contact with the plug 253 across the entire or most of the thickness 254 (e.g., over a full surface of the plug 253). The source 260 may thereby be formed without any materials entering the second cavity 235 or other unintended areas of the apparatus. Because the plug 253 extends along the y-direction, even in regions of the apparatus where the memory cell channels were removed due to etching, the entire structure is protected from the backside source diffusion, including those areas that do not include memory channels. For example, as illustrated in the B-B′ cross-sectional view of the memory architecture 200-h, the second cavity 235 may not include any of the source material after the formation of the source 260 because the plug 253 may stop the diffusion of the source material elsewhere in the structure.

The layers of metal material 204 may be word lines configured to access memory cells 105-c, 105-d, and 105-e within the respective layer. For example, a memory cell 105 may be formed at each junction of the storage material 290 with a respective layer of the metal material 204 and a respective memory channel including the conductive material 250. The memory cells 105-c, 105-d, and 105-e illustrated in FIG. 2H may be included in a memory cell pillar, in some examples. The memory cell pillars may be referred to as strings, in some examples (e.g., multiple memory cells 105 connected in series). Although not illustrated, it is to be understood that three more memory cells 105 may be included in the other side of the A-A′ cross-sectional view of the memory architecture 200-h.

A given memory cell 105 may be accessed by activation of both a corresponding word line and a corresponding memory channel at the same time. The activation of the word lines (e.g., the metal material 204) may be controlled via one or more word line decoders or other circuitry, which may be positioned under the array (e.g., within a substrate or elsewhere in the memory architecture 200-g). The activation of the memory channels may be controlled via a transistor or other selection circuitry, which may include the plug 253, the source 260, and the selector 265. For example, a voltage may be applied via the source 260, and the voltage that passes through to the plug 253 and corresponding memory channels may be controlled by the selector 265 (e.g., a gate at least partially surrounding the plug 253, an electrode). The voltage may be referred to as a threshold voltage, in some examples. The selector 265 may be relatively close to the source 260 (e.g., closer than the other layers of the metal material 204 to the n+diffusion point), which may provide for more accurate and reliable control of the threshold voltage (e.g., a gate-source voltage) and corresponding current through the conductive material 250 than if the selector 265 is positioned a further distance from the source 260. In some examples, the memory channels 270 may represent examples of string lines, and one or more bit lines may extend in the y-direction above the stack of materials 205. The one or more bit lines may be coupled with the memory channels 270 via one or more other selectors. The one or more bit lines may activate the memory channels 270, and the source 260 may bias the memory channels 270.

As described herein, the source 260 may be doped with one or more different materials to form at least two doped regions that are included in or otherwise coupled with the source 260. By including at least two regions that are doped with opposite charges, the memory system may support improved biasing and selection of the memory channels 270 for both program and erase operations.

FIG. 2I illustrates an example of a memory architecture 200-i after the fourth processing step described herein. The memory architecture 200-i illustrates the memory architecture 200-h from a trimetric viewpoint. That is, a portion of the architecture in the y-direction is further shown in FIG. 2I to further illustrate the memory channels 270 (e.g., memory channels 270-c, 270-d, and 270-e) and the spacing between them in more detail than shown in the previous figures.

The source 260 may be formed across a bottom of the structure and may be in contact with a surface of the plug 253 in the x- and y-directions. The selector 265 may include the metal material 204 and may extend along the x- and y-directions around the plug 253. That is, the first protective liner 245, the second protective liner 240, and the storage material 290 may be positioned on each side of the plug 253 between the plug 253 and the selector 265. The protective liners 245 and 240, as well as the storage material 290, may continue to extend vertically through the stack. Multiple memory cells 105 may be formed at junctions of the storage material 290, the word lines (e.g., the layers of the metal material 204) and the memory channels 270, as described and illustrated in FIG. 2H.

The memory channels 270 may represent rectangular or curved U-shaped segments that extend from the plug 253. For example, each memory channel 270 may be in contact with (e.g., coupled with) the plug 253 at a respective base contact region 271. The memory channel 270 may extend horizontally on each side of the base contact region 271. The memory channel 270 may extend vertically from the horizontal segments on each side of the base contact region 271 and along sidewalls of the stack of materials including the oxide material 203 and the metal material 204 (e.g., word lines). In some examples, a channel oxide material 255 may be positioned on top of the memory channels 270. Each memory channel 270 may be physically separated from (e.g., independent from, not in contact with) each other memory channel 270. For example, the memory channel 270-c may not be in direct contact with the memory channel 270-d or the memory channel 270-e outside of the base contact regions 271 at which each of the memory channels 270 contacts the plug 253. In some examples, a region where a memory channel 270 extends vertically along the second protective liner 240 and corresponding storage material 290 may be referred to as a memory cell channel, as there may be multiple memory cells 105 stacked in that area (e.g., at each layer of the metal material 204).

As described with reference to FIG. 2H, the selector 265 may be configured to adjust, based on a voltage applied to the selector 265, a current that flows through the plug 253 and corresponding memory channels 270 from the source 260. In some examples, the selector 265 may activate one or more different doped regions within the source 260, as described herein. The doped regions, when activated may generate current for different types of access operations, which may improve reliability and performance of the memory system. The apparatus may thereby select one or more memory cells 105 by activating, using the source 260 and the selector 265, the memory channels 270-c, 270-d, and 270-e, and activating one or more of the word lines (e.g., the layers of the metal material 204) that are at the same level as the target memory cell(s) 105.

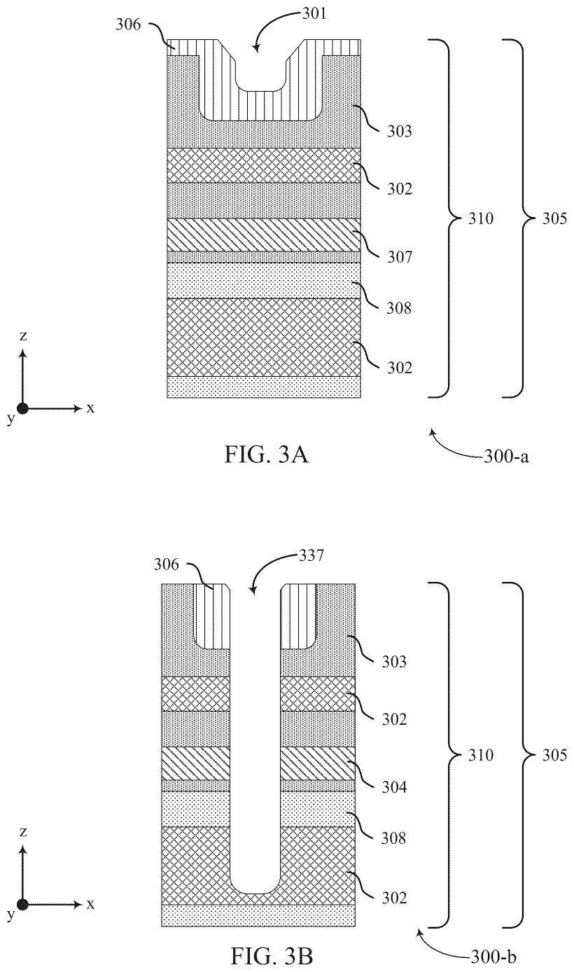

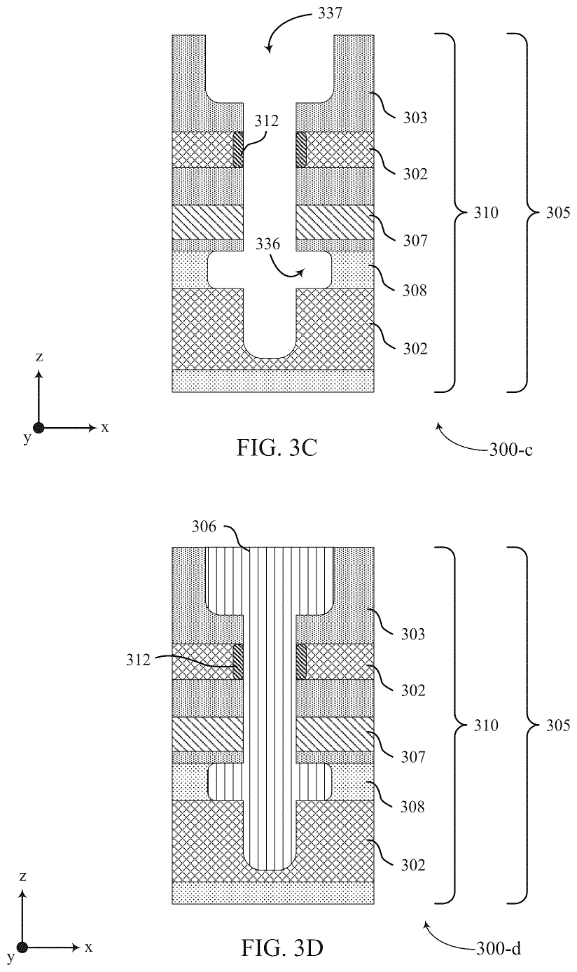

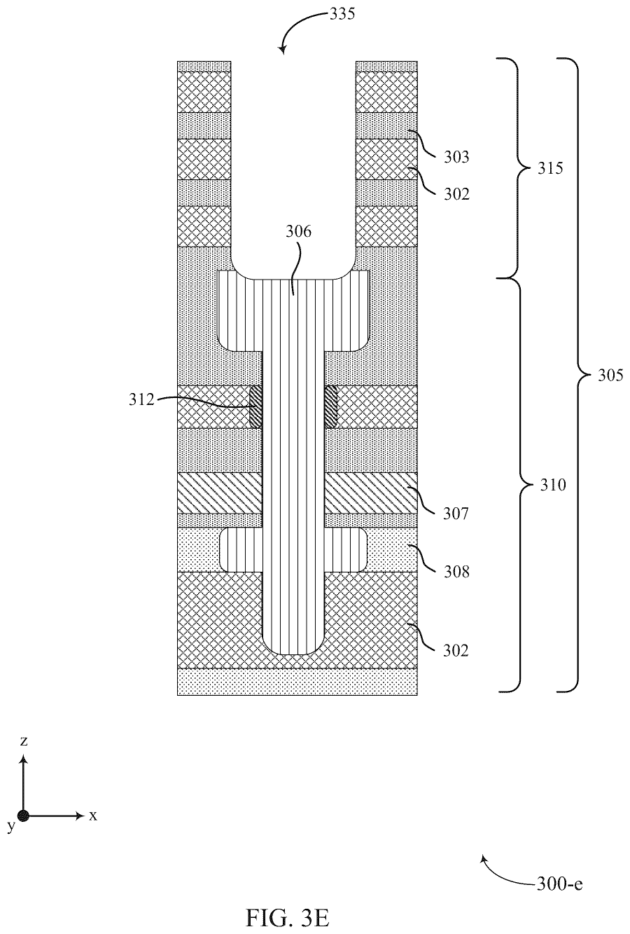

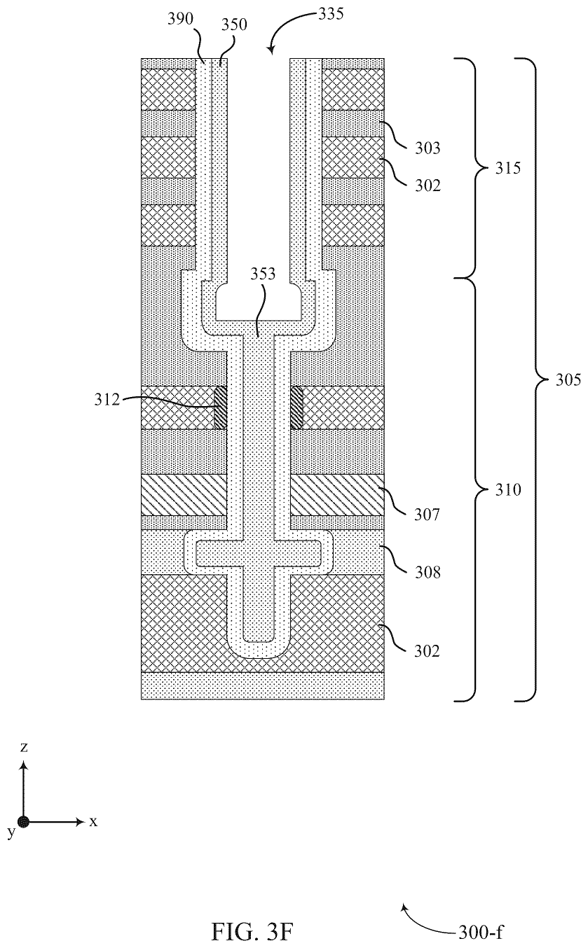

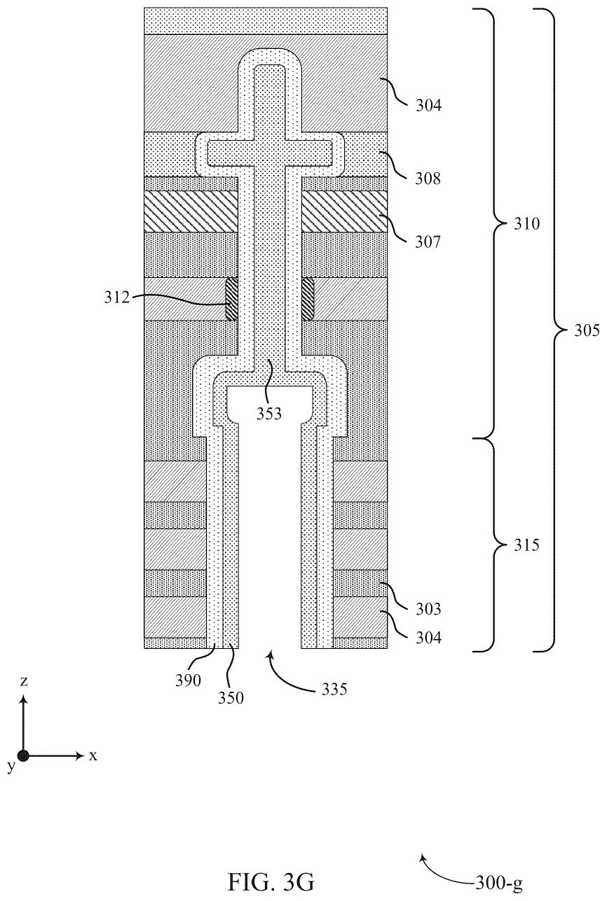

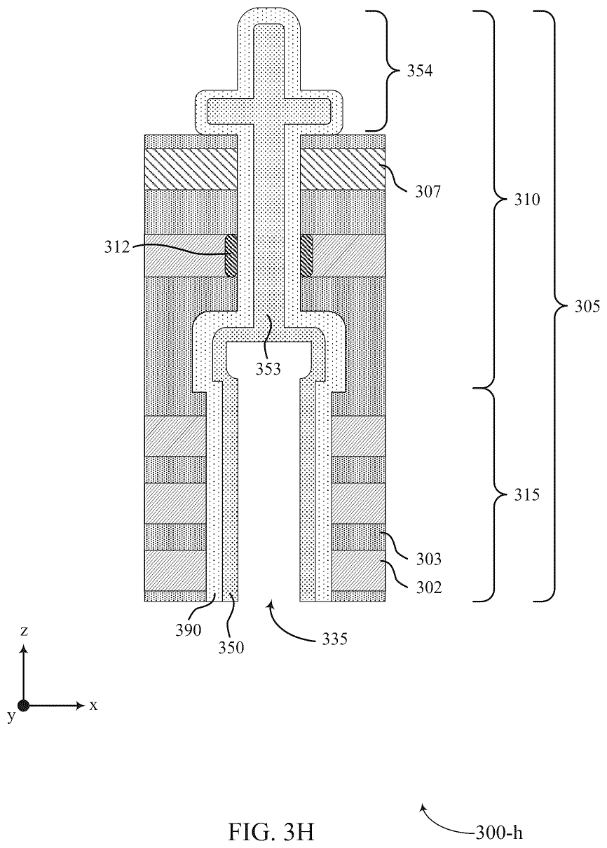

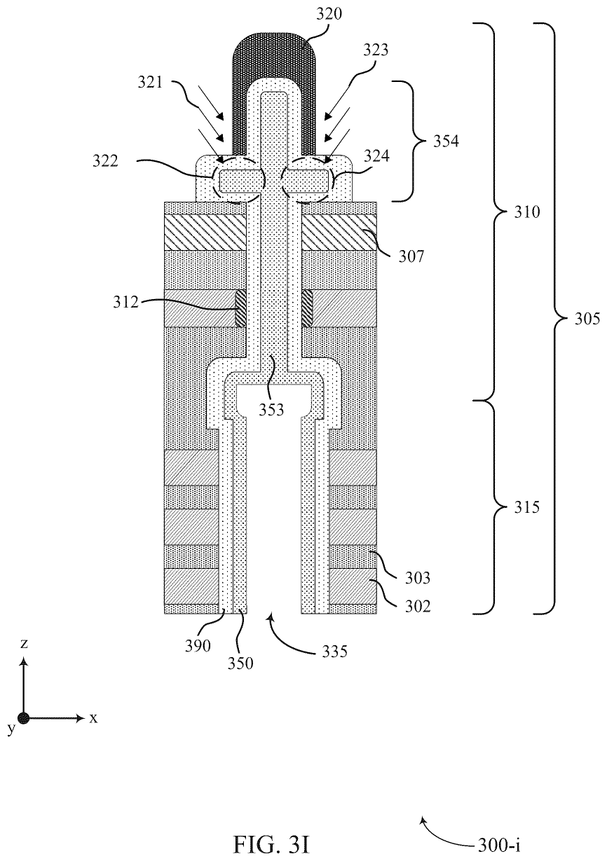

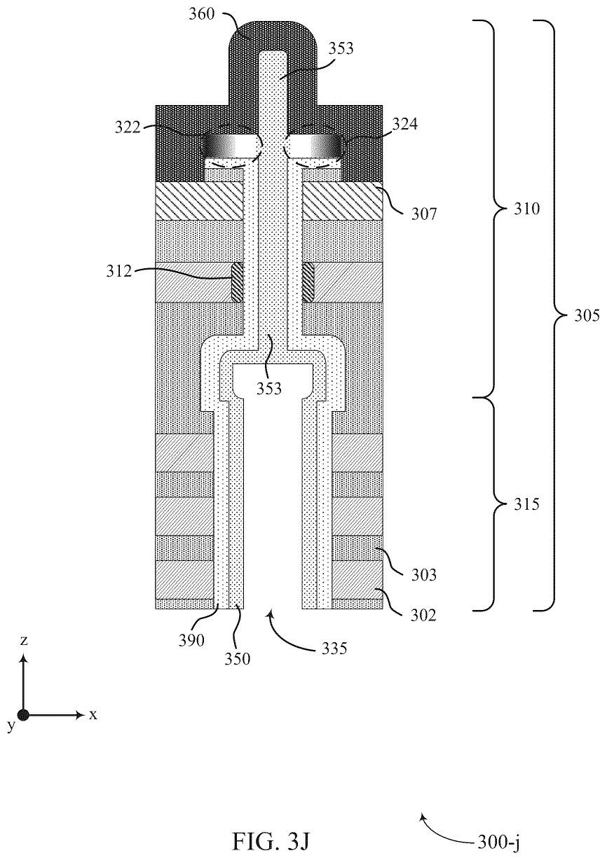

FIGS. 3A through 3J show examples of memory architectures 300 that support formation of an apparatus including p-type and n-type doping of a backside source for memory channels in accordance with examples as disclosed herein. The memory architectures 300 may be an example of a portion of an apparatus, such as an apparatus 100. FIGS. 3A through 3J show various views (e.g., diagonal or trimetric views, planar views, other views) of a memory architecture 300, which may be an example of a memory architecture implemented by an apparatus 100, as described with reference to FIG. 1. The memory architectures 300 may illustrate operations associated with forming an apparatus including memory cell channels across one or more levels of the apparatus that are connected with respective bit lines and are biased in accordance with a source having at least two regions doped with different electrical charges. Performing the processing steps may consolidate processing steps otherwise associated with forming a memory architecture. For example, the processing steps may support reduced diffusion of a source material to unnecessary regions of an apparatus, while maintaining separation between doped regions within a source to improve access operations, among other advantages.

For illustrative purposes, aspects of the memory architecture may be described with reference to an x-direction, a y-direction, and a z-direction of the illustrated coordinate systems. For example, memory architectures 300-a through 300-j may illustrate the memory architecture with a cross-sectional and/or planar view, such that a portion of the memory architecture may be removed from a trimetric view to illustrate a cross-section of the memory architecture in the xz-plane, the xy-plane, or both. Although the memory architectures 300 illustrate examples of relative dimensions and quantities of various features, aspects of the memory architectures 300 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 3A through 3J may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, processing steps performed by such a manufacturing system may be supported by one or more controllers, such as one or more processors or processing circuitry, or its components as described herein.

FIG. 3A illustrates an example of a memory architecture 300-a after a first processing step associated with forming a first level 310 of a stack of materials 305. For example, forming the stack of materials 305 may include depositing alternating (e.g., or at least partially alternating) layers of an oxide material 303 and a sacrificial material 302 above a substrate (e.g., a plane or sheet in the xy-plane on which subsequent memory materials may be formed. The substrate may be associated with CMOS circuitry. In some such examples, depositing the alternating layers may include depositing a layer of the oxide material 303, then depositing a layer of the sacrificial material 302 above the layer of the oxide material 303. Accordingly, the sacrificial material 302 and the oxide material 303 may be similarly deposited to form alternating layers, where the height of the first level 310 of the stack of materials 305 may be based on the quantity and height of each of the alternating layers. In some implementations, the oxide material 303 may be a dielectric material, such as silicon oxide, silicon oxycarbide, silicon oxynitride, or silicon nitride. In some implementations, the sacrificial material 302 may be a variation of nitride.

In some examples, as illustrated in FIG. 3A, one or more of the alternating layers may include a polysilicon material 308. For example, a polysilicon material 308 may be formed below and above a first layer of the sacrificial material 302. In some examples, one or more layers of a second sacrificial material 307 may be formed within the first level 310. The second sacrificial material may be some different variation of nitride, such as carbon nitride.

After the layers of the first level 310 are formed, a top layer of the oxide material 303 may be partially etched to form an initial recess 301. For example, a top portion of the oxide material 303 may be removed. After the recess 301 is formed, a placeholder material 306 (e.g., a sidewall material, such as a nitride or high-k material) may be formed on top of the oxide material 303 and the recess 301. The placeholder material 306 may be formed such that a portion of the recess 301 remains, as shown.

FIG. 3B illustrates an example of a memory architecture 300-b after one or more second processing steps associated with etching the stack of materials 305. For example, after the placeholder material 306 is formed on top of the first level 310, another etch may be performed to etch through at least a portion of the first level 310 in a vertical direction. The etch may form the cavity 337, which may extend from a top surface of the first level 310 of the stack of materials 305 through one or more layers of the stack of materials 305. The cavity 337 may not extend all the way to the substrate, in some examples. For example, the cavity 337 may extend through a portion of the first layer of the sacrificial material 302 that is closest to the substrate.

In some examples, the etch may planarize a top surface of the first level 310. For example, a portion of the placeholder material 306 that was previously on a top surface of the oxide material 303 may be removed, such that a top surface of the oxide material 303 is exposed and planar, and two separate portions of the placeholder material 306 may remain on either side of a top portion of the cavity 337.

FIG. 3C illustrates an example of a memory architecture 300-c after one or more third processing steps associated with further etching the stack of materials 305. For example, after the cavity 337 is formed, another one or more etch operations may be performed to expand the cavity 337. The etch operations may remove the remaining portions of the placeholder material 306 to expand the cavity 337 within the top layer of the oxide material 303. A width of the cavity 337 in the top layer of the oxide material 303 may be wider than a width of the cavity 337 at other layers.

The one or more etch operations may further etch, via the cavity 337, one or more recesses 336 in a top layer of the polysilicon material 308. For example, a portion of the polysilicon material 308 may be removed from each side of the cavity 337 in the horizontal direction to form a respective recess 336 on each side of the cavity 337. The remaining cavity 337 and recesses 336 may form a t-shape cavity.

The one or more third processing steps may further include an oxidization process to oxidize an exposed surface of the top layer of the sacrificial material 302 (e.g., a nitride material). The oxidization process may be performed before or after the etching operations. The oxidization process may form an oxidized region 312 (e.g., an oxidized dielectric) on the sacrificial material 302 that is exposed within the cavity 337 at the top layer. The oxidization process may not oxidize the sacrificial material 302 at every layer of the stack of materials 305 based on a targeted or directed oxidization, one or more masks, or both.

FIG. 3D illustrates an example of a memory architecture 300-d after one or more fourth processing steps associated with re-forming the placeholder material 306. For example, the one or more fourth processing steps may include filling the cavity 337 and the recesses 336 with the placeholder material 306. The placeholder material 306 may be formed within any open space previously etched out as part of formation of the cavity 337 and the recesses 336. In some examples, the placeholder material 306 may be formed such that a top surface of the placeholder material 306 is planar with a top surface of the oxide material 303 in the first level 310 of the stack of materials 305. The placeholder material 306 may be an etching stop material (e.g., aluminum oxide) or some other material. The placeholder material 306 may be formed via chemical mechanical planarization, in some examples.

FIG. 3E illustrates an example of a memory architecture 300-e after one or more fifth processing steps associated with formation of a second level 315 of the stack of materials 305. After the placeholder material 306 is formed and planarized, a second level 315 of the stack of materials 305 may be formed. Forming the second level 315 of the stack of materials 305 may include forming one or more layers of the oxide material 303 and the sacrificial material 302. The one or more layers of the oxide material 303 and the sacrificial material 302 may be formed on top of the top layer of the first level 310 of the stack of materials 305, including on top of the placeholder material 306. In this example, three additional layers of the sacrificial material 302 may be formed and may alternate with layers of the oxide material 303. However, it is to be understood that any quantity and pattern of layers may be formed.

After the second level 315 of the stack of materials 305 is formed, the one or more fifth processing steps may further include another etch operation to etch a second cavity 335 in the second level 315. The etch operation may remove portions of the oxide material 303 and the sacrificial material 302 from one or more layers until a top surface of the placeholder material 306 is exposed. In some examples, a portion of the placeholder material 306 may additionally be removed during the etch. The second cavity 335 may extend from a top surface of the second level 315 to a top surface of the first level 310 of the stack of materials 305 and may be relatively aligned with (e.g., along a same central axis as) the cavity 337 described with reference to FIG. 3C.

FIG. 3F illustrates an example of a memory architecture 300-f after one or more sixth processing steps associated with removal of the placeholder material 306 and formation of a memory channel. After the second cavity 335 is formed, the placeholder material 306 may be removed (e.g., etched, exhumed) via the second cavity 335. The removal of the placeholder material 306 may temporarily re-expose the cavity 337 and the recesses 336 illustrated in FIG. 3C in addition to the second cavity 335.

After the placeholder material 306 is removed, one or more layers of materials may be formed within the cavities and the recesses 336 as part of the one or more sixth processing steps. The layers of materials may include, for example, a storage material 390 and a conductive material 350. The materials may be deposited and subsequently etched back to form liners that extend along internal sidewalls of the stack of materials 305. For example, the storage material 390 may be deposited and may extend along sidewalls of the stack of materials 305 within the cavity 337, within the recesses 336, and within the second cavity 335. The storage material 390 may be formed with a relatively even thickness along sidewalls of the cavities.

After the storage material 390 is formed, a conductive material 350 may be formed on top of the storage material 390. The conductive material 350 may be deposited within remaining space in the recesses 336 and a portion of the cavity 337. For example, the conductive material 350 may fill most of the cavity 337. The conductive material 350 within the first level 310 of the stack of materials 305 may be referred to as a plug 353, in some examples. The plug 353 may represent an example of the plug 253 described with reference to FIGS. 2A through 2I. In the second level 315 of the stack of materials 305, the conductive material 350 may be formed as a liner and a portion of the second cavity 337 may remain between each side of the conductive material 350. The conductive material 350 within the second level 315 may form one or more memory channels, as described with reference to FIGS. 2A through 2I. For example, the conductive material 350 may extend along sidewalls of the second cavity 337, with the storage material 390 positioned between the stack of materials 305 and the conductive material 350.

FIG. 3G illustrates an example of a memory architecture 300-g after one or more seventh processing steps associated with flipping the apparatus and performing a replacement gate process. After the storage material 390 and the conductive material 350 are formed, the apparatus may be rotated (e.g., flipped) around 180 degrees, such that a top surface of the stack of materials 305 may be facing downward and a bottom surface may be facing upward. The rotation of the stack of materials 305 may be performed in preparation for a formation of a source via a backside of the apparatus, as described in further detail with reference to FIGS. 3H through 3J.

The one or more seventh processing steps may further include a replacement gate process, which may be performed before, after, or concurrently with the flipping of the apparatus. The replacement gate process may be referred to as a metallization process herein and may be performed to convert the sacrificial material 302 to the metal material 304. The stack of materials may thereby include layers of the oxide material 303 and layers of the metal material 304. The metallization may not alter the structure of the storage material 390, the plug 353, the conductive material 350, or the oxide material 303. In some examples, a portion of the sacrificial material 302 positioned between the two layers of the polysilicon material 308 may be replaced with the metal material 304. Additionally, or alternatively, the portion of the sacrificial material 302 between the two layers of the polysilicon material 308 may remain (e.g., may not be replaced with the metal material 304) after the metallization.

FIG. 3H illustrates an example of a memory architecture 300-h after one or more eighth processing steps. The one or more eight processing steps may include etching the now exposed backside of the stack of materials 305. That is, after the apparatus is flipped, a bottom layer of the polysilicon material 308 and the metal material 304 (e.g., or sacrificial material 302) may be exposed (e.g., instead of in contact with a substrate) and may be available for modification. The etching may include one or more surface poly strips to strip the polysilicon material 308, one or more nitride strips to strip the sacrificial material 302 or metal material 304, and another one or more surface poly strips to remove the remaining portion of the polysilicon material 308. Thus, the etch may include removing at least a portion of one or more bottom layers of the polysilicon material 308 and the metal material 304 to expose a portion 354 of the storage material 390 at least partially surrounding (e.g., lining) the plug 353. The exposed portion 354 may form a t-shape, where two segments may extend horizontally (e.g., in the x-direction) where the recesses 336 were previously located.

FIG. 3I illustrates an example of a memory architecture 300-i after one or more ninth processing steps associated with doping the exposed portion 354 of the plug 353. After the portion 354 of the plug 353 is exposed, a masking material 320 may be formed. The masking material 320 may be formed along sidewalls of the vertical segment of the plug 353 that is exposed. The masking material may not be formed over the exposed portion 322 or the exposed portion 324 that extend horizontally in the x-direction, as shown. In some examples, the storage material 390 may be removed (e.g., etched, exhumed) from the exposed portion 354 (e.g., and/or one or both of the exposed portions 322 and 324) before the masking material 320 is formed. Additionally, or alternatively, the storage material 390 may remain positioned between the masking material 320 and the plug 353. The masking material 320 may be formed via an anisotropic material deposition or some other formation.

After the masking material 320 is formed, one or more directional doping operations may be performed on the exposed portions 322 and 324 of the plug 353. For example, a first directional doping operation may be performed on the exposed portion 322 to dope the conductive material 350 within the exposed portion 322 with an n-type dopant 321. The n-type dopant 321 may be a material with a relatively high concentration of negative ions, such as phosphorous, or some other type of material. The directional doping may include expelling particles of the n-type dopant 321 toward the exposed portion 322 in a mostly horizontal direction (e.g., in the x-direction) or a diagonal direction (e.g., in the x-direction and the y-direction), as shown by the arrows in FIG. 3I. That is, the n-type dopant 321 may be pushed toward the exposed portion 322 in a certain direction such that the n-type dopant 321 either contacts the exposed portion 322 or the masking material 320, but most of the n-type dopant 321 avoids other portions of the stack of materials 305, including the exposed portion 324 on the other side of the masking material 320. The n-type dopant 321, when deposited or implanted into the conductive material 350 within the exposed portion 322, may provide the exposed portion 322 with a relatively negative charge.

A second directional doping operation may be performed on the exposed portion 324 to dope the conductive material 350 within the exposed portion 324 with a p-type dopant 323. The p-type dopant 323 may be a material with a relatively high concentration of positive ions, such as boron, or some other type of material. The second directional doping may include expelling particles of the p-type dopant 323 toward the exposed portion 324 in a mostly horizontal direction (e.g., in the x-direction) or a diagonal direction (e.g., in the x-direction and the y-direction), as shown by the arrows in FIG. 3I. That is, the p-type dopant 323 may be pushed toward the exposed portion 324 in a certain direction such that the p-type dopant 323 either contacts the exposed portion 324 or the masking material 320, but most of the p-type dopant 323 avoids other portions of the stack of materials 305, including the exposed portion 322 on the other side of the masking material 320. The p-type dopant 323, when deposited or implanted into the conductive material 350 within the exposed portion 324, may provide the exposed portion 324 with a relatively positive charge. The first and second directional doping operations may be performed concurrently or during at least partially overlapping time periods, or in any order.

After the directional doping is complete, the exposed portion 322 may be an N+ poly or other type of material, and the exposed portion 324 may be a P+ poly or other type of material. There may be two separately doped regions within the apparatus. The plug 353 may remain positioned between the exposed portion 322 and the exposed portion 324. The plug 353 may include the undoped conductive material 350, which may separate the exposed portions 322 and 324. In some examples, the exposed portions 322 and 324, as well as the plug 353, may extend in the z-direction (e.g., into and/or out of the page), as described with reference to FIGS. 2A through 2I.

FIG. 3J illustrates an example of a memory architecture 300-j after one or more tenth processing steps associated with forming a source 360. After the doping operations are performed, the one or more tenth processing steps may include removing any exposed storage material 390 via an etch or other removal process (e.g., if the storage material 390 was not already removed). The exposed portion 354 of the plug 353 may subsequently be fully exposed, with only the exposed portions 322 and 324 and the vertical extension of the plug 353 extending vertically between the exposed portions 322 and 324.

After the storage material 390 is removed, a backside source 360 may be formed (e.g., via a backside source formation operation). The source 360 may be formed via a source material deposition, which may be an N+ source poly deposition, or some other type of deposition. The source 360 may be formed over the exposed portion 354. For example, the source 360 may be formed over a top surface of the oxide material 303, over sidewalls of each of the exposed portions 322 and 324, and over sidewalls of the vertical extension of the plug 353.

In some examples, the one or more tenth processing steps may include performing an activation anneal to activate the dopants within the exposed portions 322 and 324. The resulting apparatus after the one or more tenth processing steps may thereby include a stack of materials 305, where a first level 310 includes alternating layers of metal material 304 (e.g., word lines) and oxide material 303, with a cavity 335 having sidewalls along which a storage material 390 and a conductive material 350 are formed. The storage material 390 and conductive material 350 may form a memory channel, as described in further detail elsewhere herein, where one or more memory cells may ultimately be formed along the memory channel at junctions of each word line and the storage material 390.

The source 360 may be used to activate the memory channel. In some examples, the doped regions coupled with the source 360 and the plug 353 may improve the memory channel activation for different types of access operations, such as program and erase operations, among other examples.

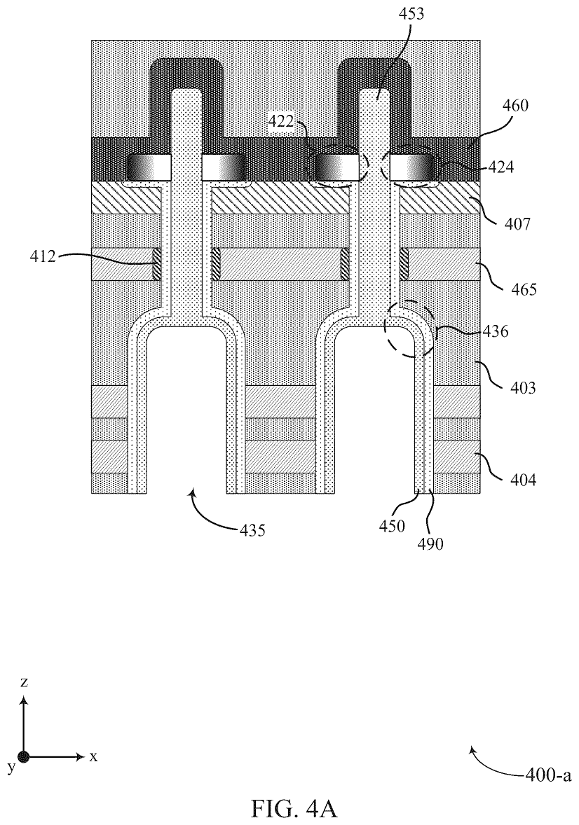

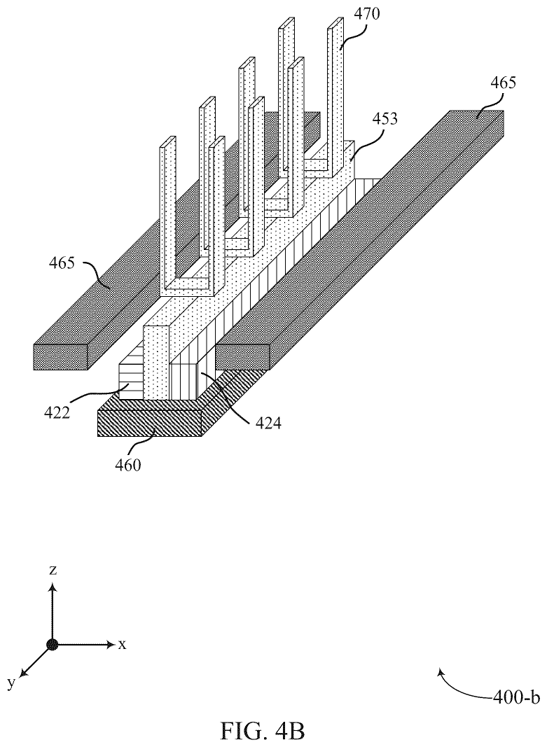

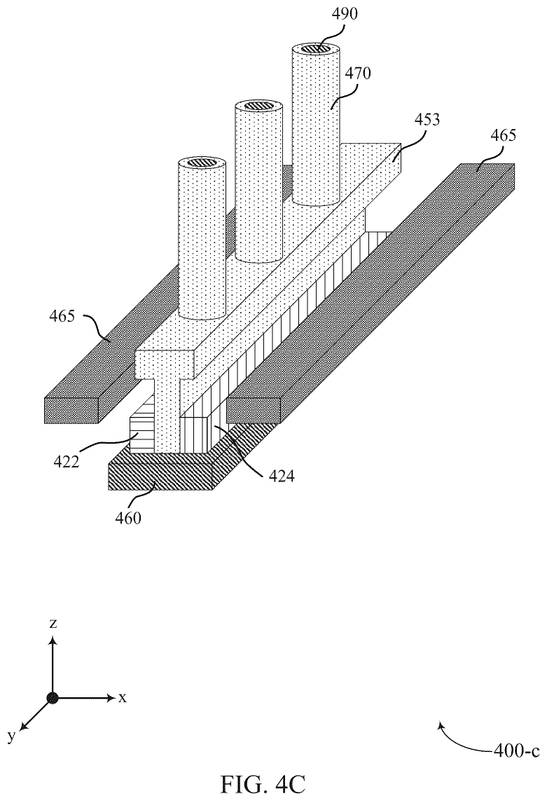

FIGS. 4A through 4C show examples of memory architectures 400 that support formation of an apparatus including p-type and n-type doping of a backside source for memory channels in accordance with examples as disclosed herein. The memory architectures 400 may be an example of a portion of an apparatus, such as an apparatus 100. FIGS. 4A through 4C show various views (e.g., diagonal or trimetric views, planar views, other views) of a memory architecture 400, which may be an example of a memory architecture implemented by an apparatus 100, as described with reference to FIG. 1. The memory architectures 400 may illustrate resulting apparatuses after performing one or more processing steps as described with reference to FIGS. 3A through 3J. The memory architectures 400 may represent various examples of apparatus that are connected with respective bit lines and are biased in accordance with a source having at least two regions doped with different electrical charges.

For illustrative purposes, aspects of the memory architecture may be described with reference to an x-direction, a y-direction, and a z-direction of the illustrated coordinate systems. For example, memory architectures 400-b and 400-c illustrate the memory architecture from trimetric views, where a substrate of the memory architecture may be associated with an xy-plane, and where the memory architecture extends a distance along the z-direction. Additionally, the memory architecture 400-a may illustrate the memory architecture with a cross-sectional and/or planar view, such that a portion of the memory architecture may be removed from the trimetric view to illustrate a cross-section of the memory architecture in the xz-plane, the xy-plane, or both Although the memory architectures 400 illustrate examples of relative dimensions and quantities of various features, aspects of the memory architectures 400 may be implemented with other relative dimensions or quantities of such features in accordance with examples as disclosed herein.

FIG. 4A illustrates an example of a memory architecture 400-a. The memory architecture 400-a may represent an example of the memory architecture 300-j after the various processing steps described with reference to FIGS. 3A through 3J. For example, the memory architecture 400-a may include a stack of alternating layers of an oxide material 403 and a metal material 404. The stack may include at least one layer of a second sacrificial material 407, which may be some variation of a nitride material, in some examples. A plug 453 of conductive material 450 may extend through at least a first portion of the stack with a storage material 490 positioned between the stack and the plug 453. The conductive material may extend along sidewalls of the stack, and the conductive material 450 may extend, from the plug 453, along the storage material 490 and sidewalls of a cavity 435. As described herein, the plug 453 may include or otherwise be coupled with a first portion 422 that has an n-type doping, and a second portion 424 having a p-type doping. The plug 453 and the portions 422 and 424 may further be coupled with a source 460. In some examples, a layer of the oxide material 403 may be formed on top of the source 460.

In the example of the memory architecture 400-a, there may be two separate sets of memory channels and corresponding plugs that are coupled with a same source 460. That is, a single apparatus may include more than one plug 453 and corresponding structures. The structures may be formed using the processing steps described and illustrated with reference to FIGS. 3A through 3J, but may be performed in two or more different regions of the stack of materials.

In this example, a junction region 436 between the plug 453 and the straight segments of conductive material 450 extending along sidewalls of the stack may be rounded (e.g., a U-shape or a C-shape), which may differ from the shape illustrated and described with reference to FIG. 3J, which may include one or more sharp corners, more than one curved segment, or any combination thereof. It is to be understood that any shape of connection between the plug 453 and the memory channels may support and operate in accordance with a source doped using the doping techniques described herein.

The memory architecture 400-a may include one or more selectors 465, which may correspond to layers of the metal material 404 that are configured to select or otherwise activate the memory channels. In some examples, the selectors 465 may be referred to as source gate select (SGS) GGs. A portion of the selector 465 that is in contact with the storage material 490 may include an oxidized region 412 (e.g., an oxidized dielectric), in some examples.

FIG. 4B illustrates a memory architecture 400-b. The memory architecture 400-b may illustrate a trimetric view of a portion of an apparatus having doped regions as described herein. The memory architecture 400-b illustrates the memory architecture 400-a from a trimetric viewpoint after the apparatus is flipped. That is, a portion of the architecture in the y-direction is further shown in FIG. 4B to further illustrate the structure of the memory channels 470, the selector 465, the doped portions 422 and 424, and the spacing between them in more detail than shown in the previous figures. The stack of materials surrounding the illustrated features may be removed for visibility and clarity purposes only, and it is to be understood that layers of oxide and metal materials may at least partially surround or otherwise be coupled with the plug 453 and the memory channels 470.

The source 460 may be formed across a bottom of the structure and may be in contact with a surface of the plug 453 in the x- and y-directions. The selector 465 may include the metal material 404 and may extend along the x- and y-directions around the plug 453. Although not illustrated in FIG. 4B, the storage material 490 may be positioned on each side of the plug 453 between the plug 453 and the selector 465. The storage material 490 may continue to extend vertically through the stack and along sidewalls of the memory channels 470, as illustrated in FIG. 4A. Multiple memory cells (not pictured in FIG. 4B) may be formed at junctions of the storage material 290, the word lines (e.g., the layers of the metal material 404) and the memory channels 470, as described and illustrated in further detail elsewhere herein, including with reference to FIGS. 2H and 2I.

The memory channels 470 may represent rectangular or curved U-shaped segments that extend from the plug 453. The memory channels 470 may represent examples of the memory channels 270 described with reference to FIG. 2I. For example, each memory channel 470 may be in contact with (e.g., coupled with) the plug 453 at a respective base contact region. The memory channel 470 may extend horizontally on each side of the base contact region. The memory channel 470 may extend vertically from the horizontal segments on each side of the base contact region and along sidewalls of the stack of materials including the oxide material 403 and the metal material 404 (e.g., word lines). In some examples, each memory channel 470 may be physically separated from (e.g., independent from, not in contact with) each other memory channel 470 outside of the base contact regions at which each of the memory channels 470 contacts the plug 453. Each of the memory channels 470 may be coupled with one or more bit lines via one or more contacts.

Although illustrated as two segments in FIG. 4B, it is to be understood that the selector 465 may connect at a point not pictured in FIG. 4B. That is, the selector 465 may be a single electrode. The selector 465 may be configured to adjust, based on a voltage applied to the selector 465, a current that flows through the plug 453 and corresponding memory channels 470 from the source 460. The selector 465 may be coupled with a voltage source, which may control a voltage applied to the selector 465. In some examples, the selector 465 may activate the n-type doped portion 422 or the p-type doped portion 424 separately from one another, as described herein.

For example, a positive voltage applied to the selector 465 (e.g., or some other voltage of a certain magnitude or sign) may activate the p-type doped portion 424, which may cause a positive current flow through the plug 453 and the memory channels 470. A negative voltage applied to the selector 465 (e.g., or some other voltage of a certain magnitude or sign) may activate the n-type doped portion 422, which may cause a negative current flow through the plug 453 and the memory channels 470. The positive current flow may facilitate or support one or more program operations to program data to one or more memory cells coupled with the memory channels 470. The negative current flow may facilitate one or more erase operations to erase data stored in the storage material 490 within one or more memory cells coupled with the memory channels 470. The selector 465 may be coupled with each of the doped portion 422 and the doped portion 424 via direct contact or one or more electrical connections. In some examples, each of the selector 465, the doped portion 422, and the doped portion 424 may extend along a length of the plug 453 in the z-direction. For example, an entire length of the plug 453 may be doped during the directional doping described with reference to FIGS. 3A through 3I. Additionally, or alternatively, the doped portion 422 and the doped portion 424 may extend a portion of the length of the plug 453.

The doped regions, when activated, may thereby generate current for different types of access operations, which may improve reliability and performance of the memory system. The apparatus may thereby select one or more memory cells by biasing, using the source 460 and the selector 465, the memory channels 470, activating the memory channels 470 via one or more bit lines (not pictured), and activating one or more of the word lines (e.g., the layers of the metal material 404) that are at the same level as the target memory cell(s).

FIG. 4C illustrates a memory architecture 400-c. The memory architecture 400-c may illustrate a trimetric view of a portion of an apparatus having doped regions as described herein. The memory architecture 400-c may include the doped portions 422 and 424, as well as the plug 453 and the selector 465 described with reference to FIGS. 4A and 4B, but may include a different shape of memory cell and channel structures. For example, the memory architecture 400-c illustrates a type of memory cell structure associated with cylindrical-shaped memory channels 470, which may at least partially surround a storage material 490.

The doped portions 422 and 424 may be formed by directional doping to an exposed portion of the plug 453, as described with reference to FIGS. 3A through 3J.

However, in this example, the memory channels 470 and the storage material 490 may be formed via one or more different processes. For example, one or more cylindrical cavities may be formed through the stack of materials, and the conductive material and the storage material 490 may be deposited within the one or more cylindrical cavities to form the cylindrical memory channels 470. One or more memory cells may be included in or otherwise coupled with the cylindrical memory channels 470 and may be activated by (e.g., accessed, programmed, or erased) by activation of the source 460 and the doped portions 422 and 424 in the same manner as described with reference to FIG. 4B.

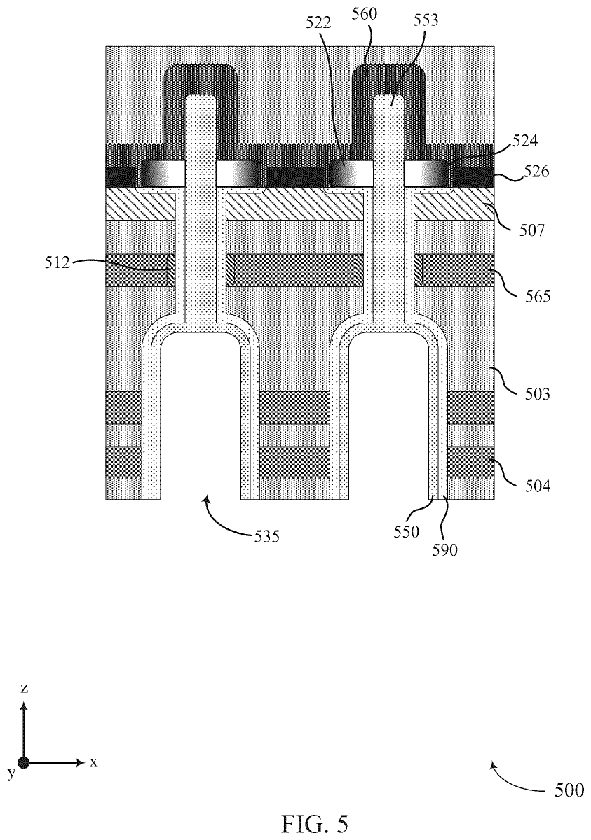

FIG. 5 shows an example of a memory architecture 500 that supports formation of an apparatus including p-type and n-type doping of a backside source for memory channels in accordance with examples as disclosed herein. The memory architecture 500 may be an example of a portion of an apparatus, such as an apparatus 100.

For illustrative purposes, aspects of the memory architecture 500 may be described with reference to an x-direction, a y-direction, and a z-direction of the illustrated coordinate systems. For example, the memory architecture 500 illustrates the memory architecture from a cross-sectional and/or planar view, such that a portion of the memory architecture may be removed from a trimetric view to illustrate a cross-section of the memory architecture in the xz-plane, the xy-plane, or both Although the memory architecture 500 illustrates examples of relative dimensions and quantities of various features, aspects of the memory architecture 500 may be implemented with other relative dimensions or quantities of such features in accordance with examples as disclosed herein.

The memory architecture 500 may represent an example of the memory architecture 400-a, with one or more additional doped regions 526. For example, the memory architecture 500 may include a stack of alternating layers of an oxide material 503 and a metal material 504. The stack may include at least one layer of a second sacrificial material 507, which may be some variation of a nitride material, in some examples. A plug 553 of conductive material 550 may extend through at least a first portion of the stack with a storage material 590 positioned between the stack and the plug 553. The storage material 590 may extend along sidewalls of the stack, and the conductive material 550 may extend, from the plug 553, along the storage material 590 and sidewalls of a cavity 535. As described herein, the plug 553 may include or otherwise be coupled with a first portion 522 that has a n-type doping, and a second portion 524 having a p-type doping. The plug 553 and the portions 522 and 524 may further be coupled with a source 560. In some examples, a layer of the oxide material 503 may be formed on top of the source 560.

In the example of the memory architecture 500, there may be two separate sets of memory channels and corresponding plugs that are coupled with a same source 560. That is, a single apparatus may include more than one plug 553 and corresponding structures. The structures may be formed using the processing steps described and illustrated with reference to FIGS. 3A through 3J, but may be performed in two or more different regions of the stack of materials.

The memory architecture 500 may include one or more selectors 565, which may correspond to layers of the metal material 504 that are configured to select or otherwise activate the memory channels. In some examples, the selectors 565 may be referred to as SGS-GGs. A portion of the selector 565 that is in contact with the storage material 590 may include an oxidized region 512 (e.g., an oxidized dielectric), in some examples.

In this example, there may be one or more additional doped portions within or otherwise coupled with the source 560. For example, one or more p-type doped regions 526 may be positioned between each of the other doped portions. That is, if there are two adjacent plugs 553, there may be a p-type doped portion 524 that is relatively near an n-type doped portion 522 (e.g., with source material between them). The p-typed doped region 526 may be positioned between these two portions to improve separation, among other examples.

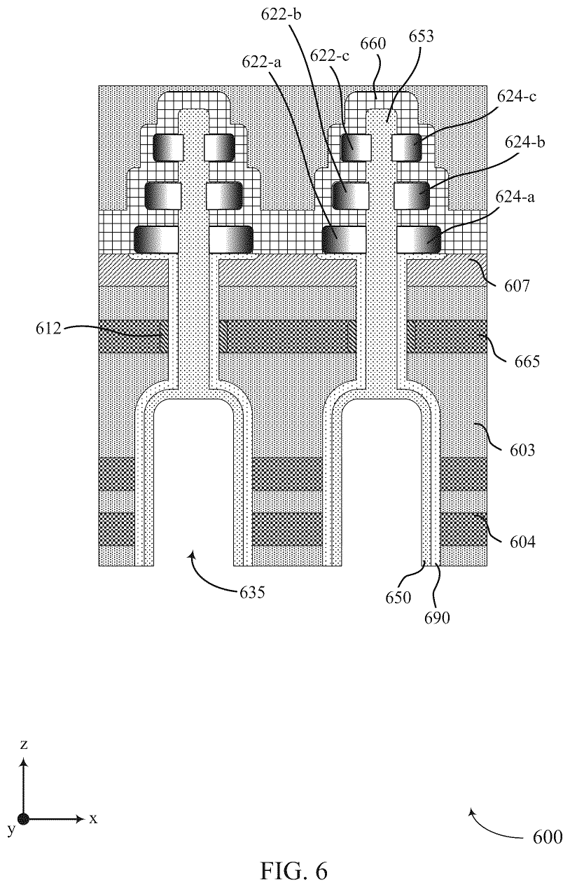

FIG. 6 shows an example of a memory architecture 600 that supports formation of an apparatus including p-type and n-type doping of a backside source for memory channels in accordance with examples as disclosed herein. The memory architecture 600 may be an example of a portion of an apparatus, such as an apparatus 100.

For illustrative purposes, aspects of the memory architecture 600 may be described with reference to an x-direction, a y-direction, and a z-direction of the illustrated coordinate systems. For example, the memory architecture 600 illustrates the memory architecture from a cross-sectional and/or planar view, such that a portion of the memory architecture may be removed from a trimetric view to illustrate a cross-section of the memory architecture in the xz-plane, the xy-plane, or both Although the memory architecture 600 illustrates examples of relative dimensions and quantities of various features, aspects of the memory architecture 600 may be implemented with other relative dimensions or quantities of such features in accordance with examples as disclosed herein.

The memory architecture 600 may represent an example of the memory architecture 400-a, with one or more additional doped regions. For example, the memory architecture 600 may include a stack of alternating layers of an oxide material 603 and a metal material 604. The stack may include at least one layer of a second sacrificial material 607, which may be some variation of a nitride material, in some examples. A plug 653 of conductive material 650 may extend through at least a first portion of the stack with a storage material 690 positioned between the stack and the plug 653. The storage material 690 may extend along sidewalls of the stack, and the conductive material 650 may extend, from the plug 653, along the storage material 690 and sidewalls of a cavity 635. As described herein, the plug 653 may include or otherwise be coupled with multiple first portions 622 (e.g., first portions 622-a, 622-b, and 622-c) that each have a n-type doping, and with multiple second portions 624 (e.g., second portions 624-a, 624-b, and 624-c) that each have a p-type doping. The plug 653 and the portions 622 and 624 may further be coupled with a source 660. In some examples, a layer of the oxide material 603 may be formed on top of the source 660.

In the example of the memory architecture 600, there may be two separate sets of memory channels and corresponding plugs that are coupled with a same source 660. That is, a single apparatus may include more than one plug 653 and corresponding structures. The structures may be formed using processing steps similar to the processing steps described and illustrated with reference to FIGS. 3A through 3J, but may be performed in two or more different regions of the stack of materials.

Additionally, there may be one or more additional recesses, similar to the recesses 336 described with reference to FIG. 3C, formed within the stack of materials. For example, there may be three recesses 336 formed on either side of a cavity, which may ultimately be filled with the conductive material 650 to form the plug 653. The three recesses on each side may be filled with the conductive material 650 and subsequently doped using one or more directional doping operation, as described in further detail elsewhere herein, including with reference to FIGS. 3G through 3J.

In some examples, the directional doping for one or more of the portions 622 or 624 may fail or may otherwise be associated with reduced doping, among other examples. As such, forming three of the doped portions 622 and three of the doped portions 624 may improve reliability by improving a likelihood that at least one of the doped portions 624 is adequately doped with a p-type dopant to produce a sufficient positive current flow for reliable programming operations and by improving a likelihood that at least one of the doped portions 622 is adequately doped with an n-type dopant to produce a sufficient negative current flow for reliable erase operations.

The memory architecture 600 may include one or more selectors 665, which may correspond to layers of the metal material 604 that are configured to select or otherwise activate the memory channels. In some examples, the selectors 665 may be referred to as SGS-GGs. A portion of the selector 665 that is in contact with the storage material 690 may include an oxidized region 612 (e.g., an oxidized dielectric), in some examples. The selector 665 may be coupled with the one or more doped portions 622 and 624 (e.g., via the plug 653 or one or more other connections. By including three of the p-type doped portions 624 and three of the n-type doped portions 622, the connection between the selector(s) 665 and the doped portions 622 and 624 may improve, which may improve a reliability of current flow.

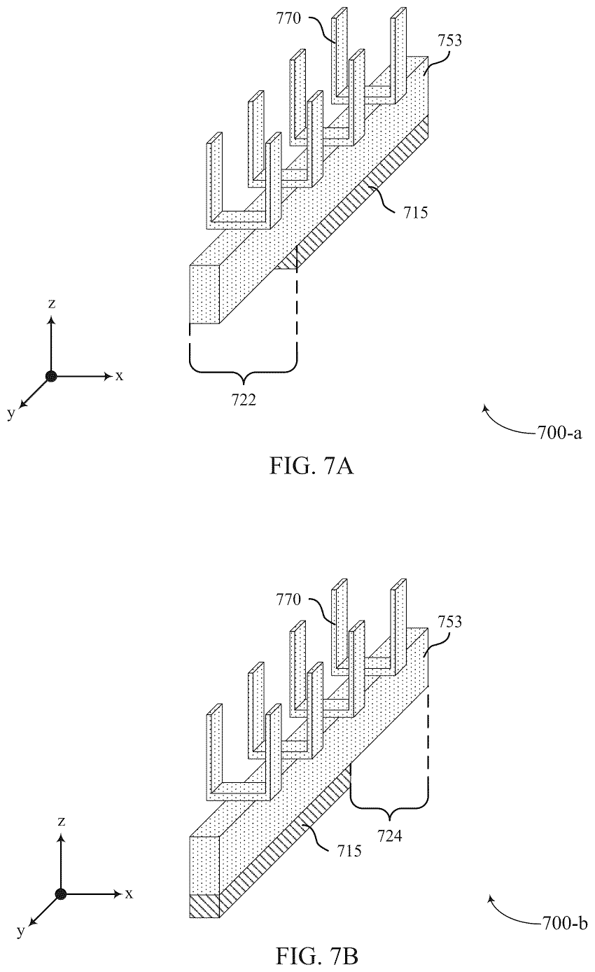

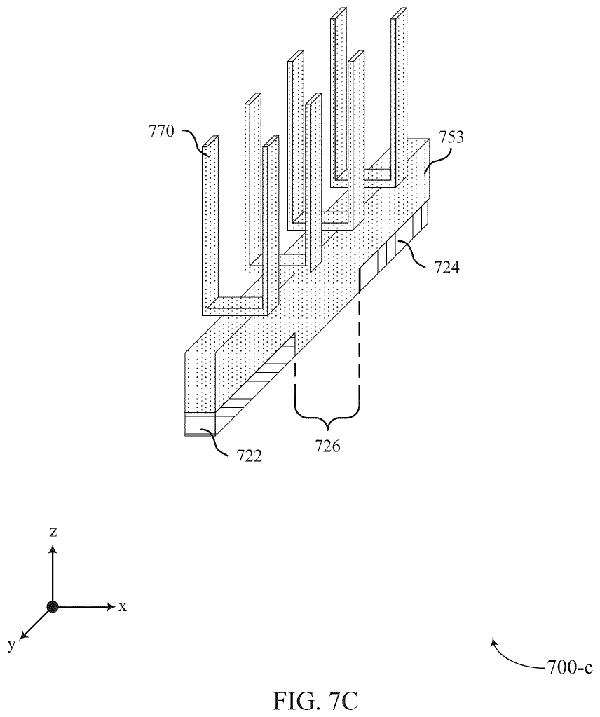

FIGS. 7A through 7C show example of memory architectures 700 that support formation of an apparatus including p-type and n-type doping of a backside source for memory channels in accordance with examples as disclosed herein. The memory architectures 700 may be an example of a portion of an apparatus, such as an apparatus 100. FIGS. 7A through 7C show various views (e.g., diagonal or trimetric views, planar views, other views) of a memory architecture 700, which may be an example of a memory architecture implemented by an apparatus 100, as described with reference to FIG. 1. The memory architectures 700 may illustrate operations associated with forming an apparatus including memory cells across one or more levels of the apparatus that are connected with respective memory channels and one or more doped regions for current activation via the memory channels. Performing the processing steps may consolidate processing steps otherwise associated with forming a memory architecture. For example, the processing steps may support reduced diffusion of a source material to unnecessary regions of an apparatus, among other advantages. In this example, the processing steps described with reference to FIGS. 7A through 7C may start with the processing steps described with reference to FIGS. 2A through 2F.

For illustrative purposes, aspects of the memory architecture may be described with reference to an x-direction, a y-direction, and a z-direction of the illustrated coordinate systems. For example, memory architectures 700-a, 700-b, and 700-c illustrate the memory architecture 700 from trimetric views, where a substrate of the memory architecture may be associated with an xy-plane, and where the memory architecture extends a distance along the z-direction. Although the memory architectures 700 illustrate examples of relative dimensions and quantities of various features, aspects of the memory architectures 700 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 7A through 7C may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, processing steps performed by such a manufacturing system may be supported by one or more controllers, such as one or more processors or processing circuitry, or its components as described herein.

FIG. 7A illustrates an example of a memory architecture 700-a. The memory architecture 700-a may represent an example of the memory architectures 200-f1 and 200-f2 after the various processing steps described with reference to FIGS. 2A through 2F and one or more additional processing steps described herein. For example, the memory architecture 700-a may include a stack of alternating layers of an oxide material 203 and a sacrificial material 202. A plug 753 of conductive material 250 may extend through at least a first portion of the stack with a storage material 290 positioned between the stack and the plug 753. The conductive material may extend along sidewalls of the stack, and the conductive material 250 may extend, from the plug 753, along the storage material 290 and sidewalls of a cavity 235 to form the memory channels 770. There may be one or more additional layers of material, such as the oxide material 225, that at least partially surround the plug 753 and/or the storage material 290. It is to be understood that all of the materials within the memory architecture 700-a may not be illustrated in FIG. 7A for clarity.

The one or more additional processing steps described herein may include etching or otherwise removing the oxide material 225 and any other materials that at least partially surround a bottom portion of the plug 753, such that at least a bottom surface of the plug 753 is exposed. In some examples, the apparatus may be flipped or otherwise rotated and the substrate may be removed such that the manufacturing system may access a “backside” of the apparatus, as described with reference to FIG. 2G. Additionally, or alternatively, the apparatus may not be flipped, and the bottom of the plug 753 may be accessed from below.

Once a surface of the plug 753 is at least partially exposed, one or more directional doping operations may be performed to dope the plug 753. As described with reference to FIG. 7A, a masking material 715 may be formed in contact with at least a portion of the exposed surface of the plug (e.g., a portion of a bottom surface of the plug 753 in the x-y plane in FIG. 7A). A remaining portion 722 of the plug 753 may be exposed. A directional doping operation may be performed to implant an n-type material (e.g., phosphorous or some other material) into the exposed portion 722 of the plug 753. The material may be implanted at least some distance into the plug 753 in the z-direction within the exposed portion 722 to form an n-type doped portion 722.

FIG. 7B illustrates a memory architecture 700-b. The memory architecture 700-b may illustrate a trimetric view of a portion of an apparatus having doped regions as described herein. The memory architecture 700-b illustrates the memory architecture 700-a from a trimetric viewpoint after the portion 722 is doped.

The masking material 715 may be removed from the plug 753 after the portion 722 is doped and may be re-formed in contact with a second portion of the plug 753. The second portion of the plug 753 may include the doped portion 722 and a central portion, which may remain neutrally charged. A remaining portion 724 of the plug 753 may be exposed after the masking material 715 is re-formed.

A second directional doping operation may be performed to implant a second material, which may be a p-type material (e.g., boron or some other material) into the exposed portion 724 of the plug 753. The second material may be implanted at least some distance into the plug 753 in the z-direction within the exposed portion 724 to form a p-type doped portion 724.

FIG. 7C illustrates a memory architecture 700-c. The memory architecture 700-c may illustrate a trimetric view of a portion of an apparatus having doped regions as described herein. The memory architecture 700-c may represent an example of the memory architecture 700-b after the masking material 715 is removed (e.g., etched, exhumed).

After the directional doping operations described herein are complete, the masking material 715 may be removed. The resulting apparatus may include the plug 753 with a p-type doped portion 724 and an n-type doped portion 722 positioned below one or more memory channels 770. The plug 753 may have a T-shape, in some examples. For example, the doped portion 722 may be a portion of conductive material that is positioned over the substrate and beneath a first portion of the plug 753. The doped portion 724 may be a portion of conductive material that is doped with a p-type dopant and is positioned over the substrate and beneath a second portion of the plug 753. There may be a third portion 726 of the plug 753 that extends from the substrate to the one or more memory channels 770 (e.g., a second level of the stack) between the first portion of the plug 753 and the second portion of the plug 753 and between the doped portion 722 and the doped portion 724. The third portion 726 of the plug 753 may represent the vertical segment within a “T,” while the first portion of the plug 753 and the second portion of the plug 753 may represent the horizontal segments extending horizontally from the vertical segment of the “T,”in some examples.

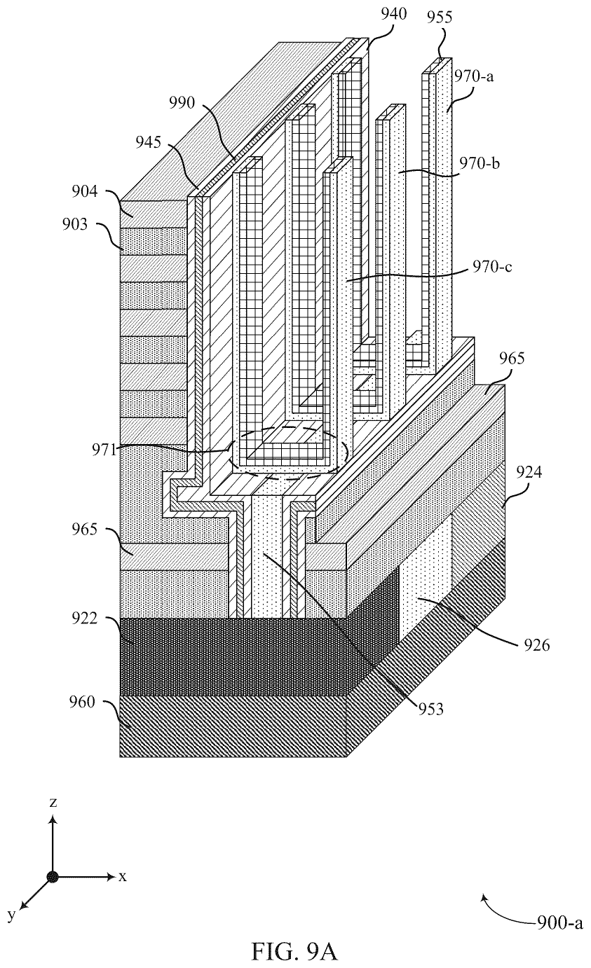

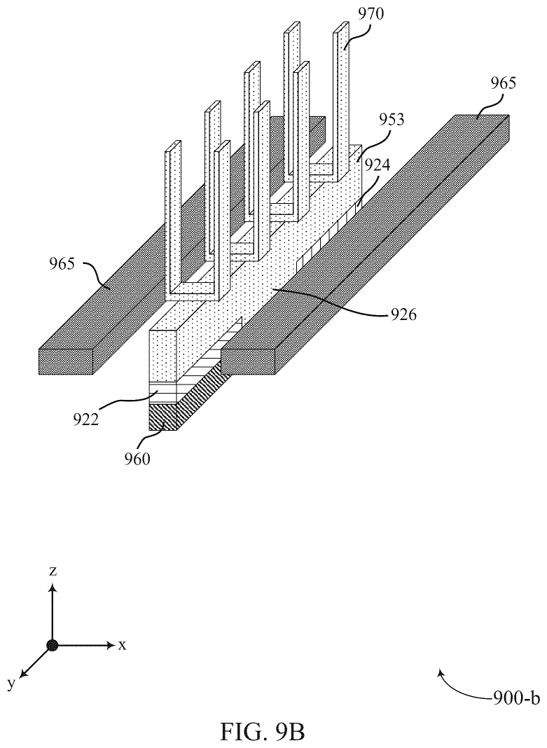

After the doped portions 722 and 724 are formed, one or more of a metallization operation and a source formation may be performed, as described in further detail elsewhere herein, including with reference to FIGS. 9A and 9B.

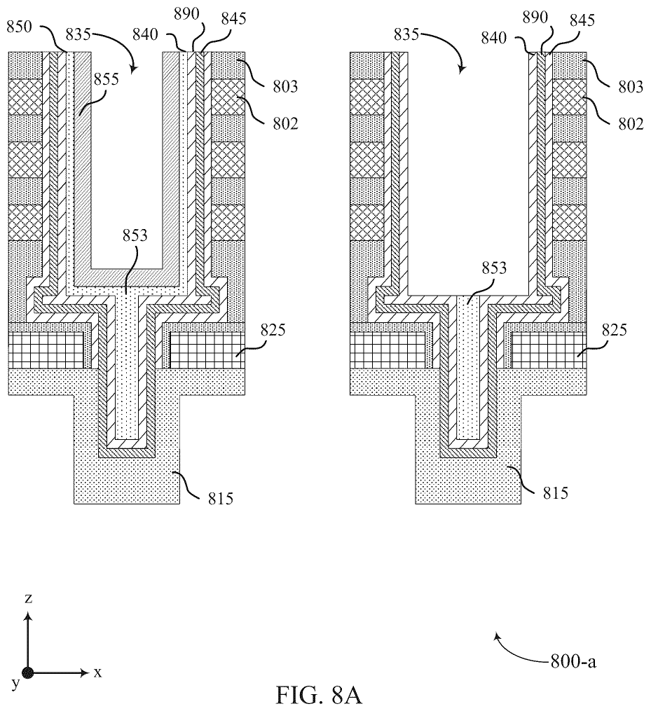

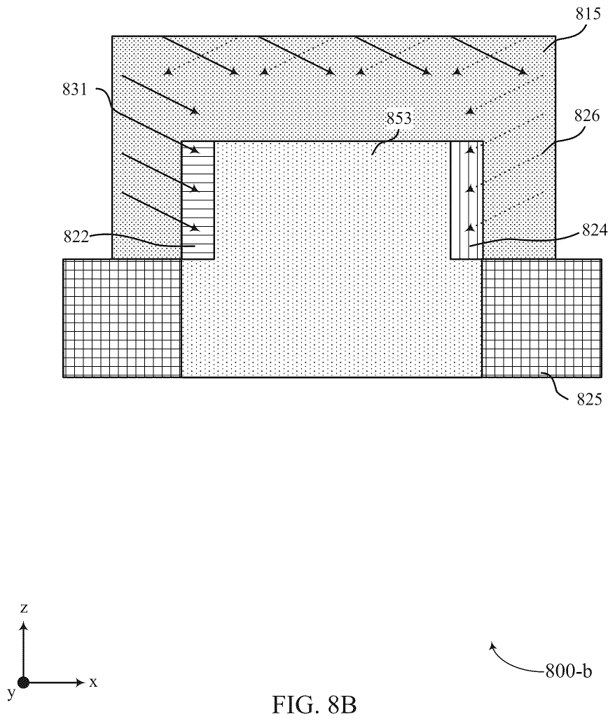

FIGS. 8A and 8B show examples of memory architectures 800 that support formation of an apparatus including p-type and n-type doping of a backside source for memory channels in accordance with examples as disclosed herein. The memory architectures 800 may be an example of a portion of an apparatus, such as an apparatus 100. FIGS. 8A through 8B show various views (e.g., diagonal or trimetric views, planar views, other views) of a memory architecture 800, which may be an example of a memory architecture implemented by an apparatus 100, as described with reference to FIG. 1. The memory architectures 800 may illustrate operations associated with forming an apparatus including memory cells across one or more levels of the apparatus that are connected with respective memory channels and one or more doped regions for current activation via the memory channels. Performing the processing steps may consolidate processing steps otherwise associated with forming a memory architecture. For example, the processing steps may support reduced diffusion of a source material to unnecessary regions of an apparatus, among other advantages. In this example, the processing steps described with reference to FIGS. 8A through 8B may start with the processing steps described with reference to FIGS. 2A through 2F.

For illustrative purposes, aspects of the memory architecture may be described with reference to an x-direction, a y-direction, and a z-direction of the illustrated coordinate systems. For example, the memory architectures 800-a and 800-b may illustrate the memory architecture with a cross-sectional and/or planar view, such that a portion of the memory architecture may be removed from the trimetric view to illustrate a cross-section of the memory architecture in the xz-plane, the xy-plane, or both. Although the memory architectures 800 illustrate examples of relative dimensions and quantities of various features, aspects of the memory architectures 800 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 8A through 8B may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, processing steps performed by such a manufacturing system may be supported by one or more controllers, such as one or more processors or processing circuitry, or its components as described herein.

FIG. 8A illustrates an example of a memory architecture 800-a. The memory architecture 800-a may represent an example of the memory architectures 200-f1 and 200-f2 after the various processing steps described with reference to FIGS. 2A through 2F and one or more additional processing steps described herein. For example, the memory architecture 800-a may include a stack of alternating layers of an oxide material 803 and a sacrificial material 802. A plug 853 of conductive material 850 may extend through at least a first portion of the stack with a storage material 890 positioned between the stack and the plug 853.

There may be one or more additional layers of material, such as the first protective liner 845 and the second protective liner 840 that line each side of the storage material 890. In some examples, a channel oxide material 855 may be formed on top of the conductive material 850 within a second level of the stack.

The memory architecture 800-a may represent an example of the memory architecture 200-e illustrated in FIG. 2E, but from a horizontal view (e.g., in the xz-plane) and with one or more additional materials. The memory architecture 800-a may represent cross sectional views of the memory architecture 200-e when cut across the A-A′ and B-B′ cross-sectional lines. When cut across the A-A′ cross-sectional line, the memory architecture 800-a may include each of the first protective liner 845, the storage material 890, and the second protective liner 840 extending along sidewalls of the stack of materials. The memory architecture 800-a may further include the conductive material 850 within both levels of the stack. For example, the conductive material 850 may form the plug 853 and may extend from the plug 853 along the storage material 890 and sidewalls of the stack within a cavity 835 to form memory channels. The channel oxide material 855, may further be included within the A-A′ cross-sectional view as a U-shape on top of the conductive material 850 in the second cavity 835. The conductive material 850 within the first level of the stack may be referred to as a plug 853 herein. For example, the plug 853 may include all of the conductive material 850 that extends continuously in the y direction through the stack of materials (e.g., to form a trench-shape). The conductive material 850 that extends from the plug 853 vertically within the second level may be referred to as segments or memory channels.

However, when cut across the B-B′ cross-sectional line, the view of the memory architecture 800-a may not include the channel oxide material 855 and may not include the conductive material 850 along the sidewalls of the second cavity 835, as described with reference to FIG. 2F.

As described herein, one or more portions of an oxide material 825 (e.g., or other placeholder material) positioned at least partially around the plug 853 in a first level of the stack may be removed. A portion of the first protective liner 845 may additionally be removed, in some cases. A masking material 815 may be formed within at least some of the area that remains after the oxide material and the first protective liner 845 are removed. The masking material 815 may contact one or more sidewalls of the plug 853, in some examples. Additionally, or alternatively, the masking material 815 may be formed in contact with the storage material 890. That is, the storage material 890 may be positioned between the masking material 815 and the plug 853. The masking material may be formed in a rectangular U-shape around the plug 853, in some examples. The masking material 815 may be an anisotropic material, or some other type of material.

FIG. 8B illustrates a memory architecture 800-b. The memory architecture 800-b may illustrate a planar vie of a portion of the memory architecture 800-a illustrated in FIG. 8A. It is to be understood that not all of the materials included in the apparatus are illustrated in FIG. 8B for clarity purposes.

In some examples, after the masking material 815 is formed around the plug, the apparatus may be flipped or otherwise rotated such that the masking material 815 is toward a top of the apparatus in the z-direction. The flipping may facilitate a backside source formation operation. As described herein, to improve current flow within the memory system, one or more doped regions may be formed before the backside source is formed.

As described herein, after the apparatus is flipped, one or more directional doping operations may be performed concurrently or in any order. A first directional doping operation may include pushing particles of a first material 831 toward a first side of the apparatus. For example, as shown by the solid arrows in FIG. 8B, the first material 831 may be pushed toward the plug 853 in a diagonal direction (e.g., downward in the z-direction and to the right in the x-direction). The first material 831 may be phosphorous or some other negatively charged material. The masking material 815 may block the portion 824 of the conductive material from being implanted with the first material 831. However, the masking material 815 may permit the first material 831 to pass through and implant within the first portion 822 of the conductive material. The first portion 822 may thereby become an n-type doped portion 822.

A second directional doping operation may include pushing particles of a second material 826 toward a second side of the apparatus. For example, as shown by the dashed arrows in FIG. 8B, the second material 826 may be pushed toward the plug 853 in a second diagonally direction (e.g., downward in the z-direction and to the left in the x-direction). The second material 826 may be boron or some other positively charged material. The masking material 815 may block the portion 822 of the conductive material from being implanted with the second material 826. However, the masking material 815 may permit the second material 826 to pass through and implant within the second portion 824 of conductive material. The second portion 824 may thereby become a p-type doped portion 824.

Although the masking material 815 is illustrated as being formed on top of an on each exposed sidewall of the plug 853, it is to be understood that, in some examples, the masking material 815 may be formed on a top surface of the plug 853, but the sidewalls may remain exposed. Additionally, or alternatively, one or more other materials, such as the storage material 890, may be positioned between the plug 853 and the masking material 815 or between the plug 853 and the oxide material 825.

The plug 853 may thereby be doped with two separate dopants using the masking material as a barrier to create the n-type doped portion 822 and the p-type doped portion 824, which are separated by a portion of the plug 853 that remains undoped.

A metallization process and a backside source formation process may subsequently be formed once the doped regions are formed and the masking material 815 is removed, as described in further detail elsewhere herein, including with reference to FIGS. 9A and 9B.

FIGS. 9A and 9B show examples of memory architectures 900 that support formation of an apparatus including p-type and n-type doping of a backside source for memory channels in accordance with examples as disclosed herein. The memory architectures 900 may be an example of a portion of an apparatus, such as an apparatus 100. FIGS. 9A and 9B show various views (e.g., diagonal or trimetric views, planar views, other views) of a memory architecture 900, which may be an example of a memory architecture implemented by an apparatus 100, as described with reference to FIG. 1. The memory architectures 900 may illustrate resulting structures within an apparatus including memory cells across one or more levels of the apparatus that are connected with respective memory channels and one or more doped regions for current activation via the memory channels. In this example, the memory architectures 900 may represent examples of resulting structures after performing the processing steps described with reference to FIGS. 7A through 7C and FIGS. 8A and 8B.

For illustrative purposes, aspects of the memory architecture may be described with reference to an x-direction, a y-direction, and a z-direction of the illustrated coordinate systems. For example, memory architectures 900-a and 900-b illustrate the memory architecture 900 from trimetric views, where a substrate of the memory architecture may be associated with an xy-plane, and where the memory architecture extends a distance along the z-direction. Although the memory architectures 900 illustrate examples of relative dimensions and quantities of various features, aspects of the memory architectures 900 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

FIG. 9A illustrates the memory architecture 900-a from a trimetric viewpoint.

That is, a portion of the architecture in the y-direction is further shown in FIG. 9A to illustrate the memory channels 970 (e.g., memory channels 970-a, 970-b, and 970-c) and the spacing between them. The memory architecture 900-a illustrates an example apparatus that includes two doped portions 922 and 924 that are on opposite ends of the plug 953 in the y-direction and are separated by a portion 926 of the plug 953. The memory architecture 900-a may be formed after the one or more processing steps described with reference to either FIGS. 7A through 7C or after the one or more processing steps described with reference to FIGS. 8A and 8B to form the two doped regions.

After the n-type doped portion 922 and the p-type doped portion 924 are formed as described herein, any remaining masking material (e.g., masking material 715 or 815) may be removed from the stack and a backside source formation may occur to form the source 960, which may be in contact with the doped portion 922, the portion 926 of the plug 953, and the doped portion 924. The apparatus may be flipped over again, such that the source 960 is in contact with or at least closer to a substrate than the remainder of the apparatus. A metallization operation may occur to replace the sacrificial material with the metal material 904, such that the apparatus may include alternating layers of the metal material 904 and the oxide material 903.

The memory channels 970 may represent rectangular or curved U-shaped segments that extend from the plug 953. For example, each memory channel 970 may be in contact with (e.g., coupled with) the plug 953 at a respective base contact region 971. The memory channel 970 may extend horizontally on each side of the base contact region 971.

The memory channel 970 may extend vertically from the horizontal segments on each side of the base contact region 971 and along sidewalls of the stack of materials including the oxide material 903 and the metal material 904 (e.g., word lines). In some examples, a channel oxide material 955 may be positioned on top of the memory channels 970. Each memory channel 970 may be physically separated from (e.g., independent from, not in contact with) each other memory channel 970. For example, the memory channel 970-c may not be in direct contact with the memory channel 970-b or the memory channel 970-a outside of the base contact regions 971 at which each of the memory channels 970 contacts the plug 953. In some examples, a region where a memory channel 970 extends vertically along the second protective liner 940 and corresponding storage material 990 may be referred to as a memory cell channel, as there may be multiple memory cells 105 stacked in that area (e.g., at each layer of the metal material 204). The second protective liner 945 may extend between the stack of materials and the storage material 990.

The memory architecture 900-a may further include the selector 965, which may be referred to as an SGS-GG, in some examples. The selector 965 may be configured to adjust, based on a voltage applied to the selector 965, a current that flows through the plug 953 and the memory channels 970 from the source 960. In some examples, the selector 965 may activate one or more different doped regions within or otherwise coupled with the source 960, as described herein. For example, the selector 965 may activate either the n-type doped portion 922 or the p-type doped portion 924, based on a voltage applied to the selector 965.

The doped portions, when activated may generate current for different types of access operations, which may improve reliability and performance of the memory system. For example, the p-type doped portion 924 may support a positive current flow for programming operations (e.g., to program one or more memory cells 105 in one or more of the memory channels 970). The n-type doped portion 922 may support a negative current flow for erase operations (e.g., to erase data stored to one or more memory cells 105 in one or more of the memory channels 970). The apparatus may thereby select one or more memory cells 105 by activating, using the source 960 and the selector 965, the memory channels 970, and activating one or more of the word lines (e.g., the layers of the metal material 904) that are at the same level as the target memory cell(s) 105. Although not pictured, it is to be understood that one or more bit lines may extend in the x-direction or the y-direction above the stack of materials and may be coupled with a top portion of each memory channel 970.

FIG. 9B illustrates the memory architecture 900-b from the trimetric viewpoint.

FIG. 9B does not include all of the materials and components illustrated in FIG. 9A to improve clarity and visibility.

As illustrated in FIG. 9B, the plug 953 may be a T-shape, with a vertical portion (e.g., 926) extending between the n-type doped portion 922 and the p-type doped portion 924 to reduce interference between the two. The memory channels 970 may be rectangular U-shaped segments, or some other shape.

The source 960 may extend beneath the doped portion 922, the portion 926 of the plug 953, and the doped portion 924. The selector 965 may include one or more segments extending in the y-direction adjacent to the plug 953. In some examples, the selector 965 may be electrically coupled with the plug 953 and the doped portions 922 and 924. Each segment of the selector 965 may be coupled with one another and a voltage source.

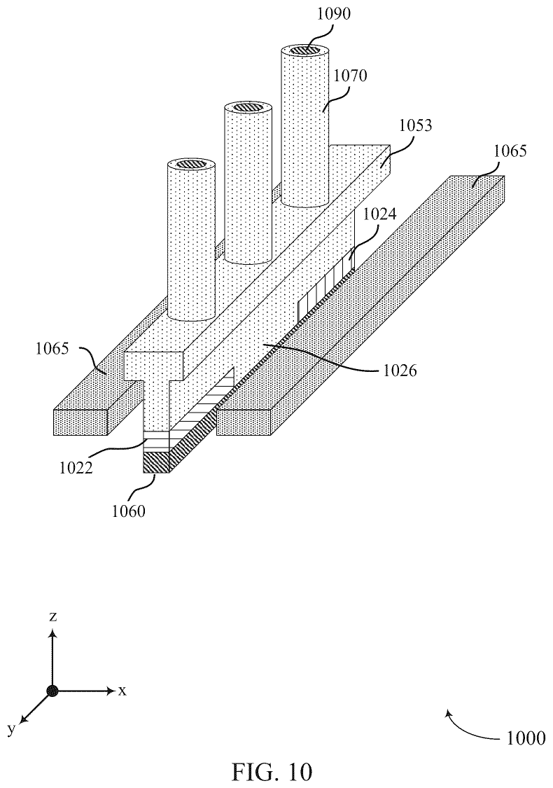

FIG. 10 shows an example of a memory architecture 1000 that supports formation of an apparatus including p-type and n-type doping of a backside source for memory channels in accordance with examples as disclosed herein. The memory architecture 1000 may be an example of a portion of an apparatus, such as an apparatus 100. FIG. 10 may illustrate resulting structures within an apparatus including memory cells across one or more levels of the apparatus that are connected with respective memory channels and one or more doped portions for current activation via the memory channels. In this example, the memory architectures 1000 may represent examples of resulting structures after performing the processing steps described with reference to FIGS. 7A through 7C and FIGS. 8A and 8B with cylindrical cell structures.

For illustrative purposes, aspects of the memory architecture 1000 may be described with reference to an x-direction, a y-direction, and a z-direction of the illustrated coordinate systems. For example, memory architecture 1000 illustrates the memory architecture 1000 from a trimetric view, where a substrate of the memory architecture may be associated with an xy-plane, and where the memory architecture extends a distance along the z-direction. Although the memory architecture 1000 illustrates examples of relative dimensions and quantities of various features, aspects of the memory architecture 1000 may be implemented with other relative dimensions or quantities of such features in accordance with examples as disclosed herein.

The memory architecture 1000 illustrated in FIG. 10 may be abstracted to improve visibility, as described with reference to FIG. 9B. For example, the memory architecture 1000 may include one or more other materials and components not illustrated in FIG. 10. The memory architecture 1000 illustrates an example apparatus that includes two doped portions 1022 and 1024 that are on opposite ends of the plug 1053 in the y-direction and are separated by a portion 1026 of the plug 1053. The memory architecture 1000 may be formed after the one or more processing steps described with reference to either FIGS. 7A through 7C or after the one or more processing steps described with reference to FIGS. 8A and 8B to form the two doped regions. However, in this example, the memory channels 1070 may be formed in cylindrical shapes (e.g., GAA cells). That is, the conductive material may be formed within one or more cylindrical holes through a stack of alternating sacrificial and oxide materials. The plug 1053 may have a similar T-shape, but may be coupled with the memory channels 270 extending vertically above the plug 1053 as shown.

The memory channels 1070 may at least partially surround the storage material 1090, in some examples. For example, a cylinder of the storage material 1090 may extend vertically within a larger cylinder of the conductive material forming the memory channels 1070. Memory cells may be located within the memory channels 1070 at each layer of the metal material (e.g., after a metallization process).

As illustrated in FIG. 10, the memory architecture 1000 including cylindrical memory channels 1070 may still support the doping described herein. For example, the directional doping operations described with reference to FIGS. 7A through 7C or with reference to FIGS. 8A and 8B may be applied to memory systems having various different shapes of memory cell channels 1070 to form memory cell channels 1070 coupled with a plug 1053 that has two different doped regions. The n-type doped portion 1022 may be positioned on one end of the plug 1053 in the y-direction, and the p-type doped portion 1024 may be positioned on an opposite end of the plug 1053 in the y-direction. The n-type doped portion 1022 and the p-type doped portion 1024 may be separated from one another by the portion 1026 of the plug 1053.

The memory architecture 1000 may further include the selector 1065, which may represent an example of the selector 965 described with reference to FIGS. 9A and 9B, and may be configured to adjust, based on a voltage applied to the selector 1065, a current that flows through the plug 1053 and the memory channels 1070 from the source 1060. In some examples, the selector 1065 may activate one or more different doped regions within or otherwise coupled with the source 1060, as described herein. For example, the selector 1065 may activate either the n-type doped portion 1022 or the p-type doped portion 1024, based on a voltage applied to the selector 1065. The doped portions, when activated may generate current for different types of access operations, which may improve reliability and performance of the memory system. For example, the p-type doped portion 1024 may support a positive current flow for programming operations (e.g., to program one or more memory cells 105 in one or more of the memory channels 1070). The n-type doped portion 1022 may support a negative current flow for erase operations (e.g., to erase data stored to one or more memory cells 105 in one or more of the memory channels 1070). The apparatus may thereby select one or more memory cells 105 by activating, using the source 1060 and the selector 1065, the memory channels 1070, and activating one or more of the word lines (e.g., the layers of the metal material) that are at the same level as the target memory cell(s) 105. Although not pictured, it is to be understood that one or more bit lines may extend in the x-direction or the y-direction above the stack of materials and may be coupled with a top portion of each memory channel 1070.

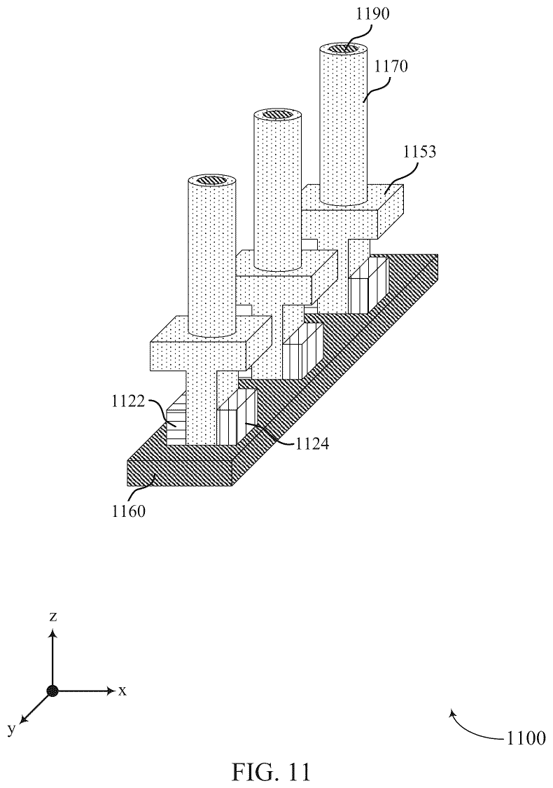

FIG. 11 shows an example of a memory architecture 1100 that supports formation of an apparatus including p-type and n-type doping of a backside source for memory channels in accordance with examples as disclosed herein. The memory architecture 1100 may be an example of a portion of an apparatus, such as an apparatus 100. FIG. 11 may illustrate resulting structures within an apparatus including memory cells across one or more levels of the apparatus that are connected with respective memory channels and one or more doped portions for current activation via the memory channels.

For illustrative purposes, aspects of the memory architecture 1100 may be described with reference to an x-direction, a y-direction, and a z-direction of the illustrated coordinate systems. For example, memory architecture 1100 illustrates the memory architecture 1100 from a trimetric view, where a substrate of the memory architecture may be associated with an xy-plane, and where the memory architecture extends a distance along the z-direction. Although the memory architecture 1100 illustrates examples of relative dimensions and quantities of various features, aspects of the memory architecture 1100 may be implemented with other relative dimensions or quantities of such features in accordance with examples as disclosed herein.

The memory architecture 1100 illustrated in FIG. 11 may be abstracted to improve visibility, as described with reference to FIG. 9B and FIG. 10. For example, the memory architecture 1100 may include one or more other materials and components not illustrated in FIG. 11. The memory architecture 1100 illustrates an example apparatus that includes separated memory channels 1170 and discrete plug structures. That is, instead of each of the memory channels 1170 being coupled with a same plug, as described with reference to FIG. 10, for example, each of the memory channels 1170 may be separately coupled with the source 1160 via separate plugs 1153, which may be isolated from one another outside of the source connection.

As described herein, when a memory architecture 1100 includes separated plugs 1153 and memory channels 1170, each of the separate plugs 1153 may be doped with two dopants. For example, using one or more of the directional doping operations described herein, a first dopant (e.g., a p-type material) may be implanted on one side of each of the plugs 1153 in the x-direction, and a second dopant (e.g., an n-type material) may be implanted on an opposite side of each of the plugs 1153 in the x-direction. The resulting structure may include the n-type doped portion 1122 and the p-type doped portion 1124, with a portion of each plug 1153 positioned between them.

The memory channels 1170 may be cylindrical and may include the storage material 1190. Additionally, or alternatively, the memory channels may be a U-shape, a rectangular U-shape, or any other shape. The doping techniques described herein may thereby apply to a variety of different memory channel shapes and sizes.

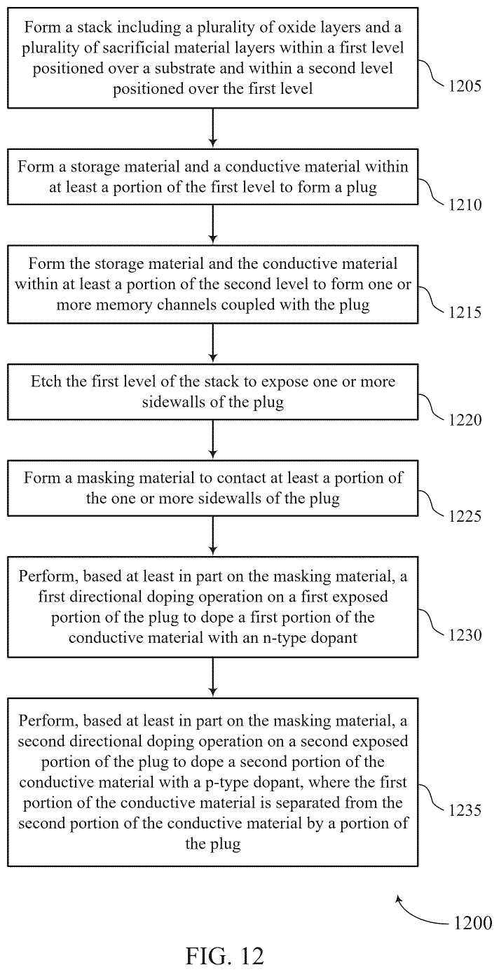

FIG. 12 shows a flowchart illustrating a method 1200 that supports formation of an apparatus including p-type and n-type doping of a backside source for memory channels in accordance with examples as disclosed herein. The operations of method 1200 may be implemented by a manufacturing system or its components as described herein. For example, the operations of method 1200 may be performed by a manufacturing system as described with reference to FIGS. 1 through 11. In some examples, a manufacturing system may execute a set of instructions to control the functional elements of the device to perform the described functions. Additionally, or alternatively, the manufacturing system may perform aspects of the described functions using special-purpose hardware.

At 1205, the method may include forming a stack including a plurality of oxide layers and a plurality of sacrificial material layers within a first level positioned over a substrate and within a second level positioned over the first level.

At 1210, the method may include forming a storage material and a conductive material within at least a portion of the first level to form a plug.

At 1215, the method may include forming the storage material and the conductive material within at least a portion of the second level to form one or more memory channels coupled with the plug.

At 1220, the method may include etching the first level of the stack to expose one or more sidewalls of the plug.

At 1225, the method may include forming a masking material to contact at least a portion of the one or more sidewalls of the plug.

At 1230, the method may include performing, based at least in part on the masking material, a first directional doping operation on a first exposed portion of the plug to dope a first portion of the conductive material with an n-type dopant.

At 1235, the method may include performing, based at least in part on the masking material, a second directional doping operation on a second exposed portion of the plug to dope a second portion of the conductive material with a p-type dopant, where the first portion of the conductive material is separated from the second portion of the conductive material by a portion of the plug.

In some examples, an apparatus as described herein may perform a method or methods, such as the method 1200. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a stack including a plurality of oxide layers and a plurality of sacrificial material layers within a first level positioned over a substrate and within a second level positioned over the first level; forming a storage material and a conductive material within at least a portion of the first level to form a plug; forming the storage material and the conductive material within at least a portion of the second level to form one or more memory channels coupled with the plug; etching the first level of the stack to expose one or more sidewalls of the plug; forming a masking material to contact at least a portion of the one or more sidewalls of the plug; performing, based at least in part on the masking material, a first directional doping operation on a first exposed portion of the plug to dope a first portion of the conductive material with an n-type dopant; and performing, based at least in part on the masking material, a second directional doping operation on a second exposed portion of the plug to dope a second portion of the conductive material with a p-type dopant, where the first portion of the conductive material is separated from the second portion of the conductive material by a portion of the plug.

Aspect 2: The method, apparatus, or non-transitory computer-readable medium of aspect 1, where forming the masking material includes operations, features, circuitry, logic, means, or instructions, or any combination thereof for forming the masking material along the one or more sidewalls of the portion of the plug, where the first portion of the conductive material and the second portion of the conductive material extend horizontally from opposite sides of the portion of the plug, and where performing the first directional doping operation includes; doping the first portion of the conductive material with the n-type dopant directed to a first side of the plug, where the masking material coupled with the portion of the plug blocks the second portion of the conductive material on a second side of the plug from the n-type dopant; where performing the second directional doping operation includes; and doping the second portion of the conductive material with the p-type dopant, where the masking material coupled with the portion of the plug blocks the first portion of the conductive material on the first side of the plug from the p-type dopant.

Aspect 3: The method, apparatus, or non-transitory computer-readable medium of any of aspects 1 through 2, further including operations, features, circuitry, logic, means, or instructions, or any combination thereof for forming the masking material between the substrate and the second exposed portion of the plug, where the first directional doping operation dopes the first portion of the conductive material in the first exposed portion of the plug based at least in part on forming the masking material between the substrate and the second exposed portion of the plug; removing, after performing the first directional doping operation, the masking material; and forming the masking material between the substrate and the first exposed portion of the plug after removing the masking material, where the second directional doping operation dopes the second portion of the conductive material in the second exposed portion of the plug based at least in part on forming the masking material between the substrate and the first exposed portion of the plug.

Aspect 4: The method, apparatus, or non-transitory computer-readable medium of any of aspects 1 through 3, where forming the masking material includes operations, features, circuitry, logic, means, or instructions, or any combination thereof for forming an anisotropic material to contact the one or more sidewalls of the plug, where the first directional doping operation and the second directional doping operation are based at least in part on the anisotropic material.

Aspect 5: The method, apparatus, or non-transitory computer-readable medium of any of aspects 1 through 4, further including operations, features, circuitry, logic, means, or instructions, or any combination thereof for removing the masking material and the storage material after performing the first directional doping operation and the second directional doping operation and forming, after removing the masking material and the storage material, a source that at least partially surrounds the plug, the first portion of the conductive material, and the second portion of the conductive material.

Aspect 6: The method, apparatus, or non-transitory computer-readable medium of any of aspects 1 through 5, further including operations, features, circuitry, logic, means, or instructions, or any combination thereof for rotating, after forming the conductive material, the stack to expose a bottom surface of the first level of the stack, where etching the first level of the stack to expose the one or more sidewalls of the plug is based at least in part on rotating the stack and performing, after forming the conductive material, a replacement gate procedure to replace the plurality of sacrificial material layers with one or more metal layers.

Aspect 7: The method, apparatus, or non-transitory computer-readable medium of any of aspects 1 through 6, where the n-type dopant includes phosphorous and the p-type dopant includes boron.

Aspect 8: The method, apparatus, or non-transitory computer-readable medium of any of aspects 1 through 7, further including operations, features, circuitry, logic, means, or instructions, or any combination thereof for etching the first level of the stack to form a first cavity that extends vertically through at least a portion of the first level of the stack; etching, via the first cavity, a first layer of the plurality of sacrificial material layers to form one or more recesses that extend within the first layer from the first cavity; forming an etch stop material in the first cavity and the one or more recesses; forming the second level of the stack above the first level of the stack and the etch stop material; etching the second level of the stack to form a second cavity that extends vertically to the etch stop material in the first level of the stack; and exhuming, via the second cavity, the etch stop material, where forming the conductive material includes forming the conductive material within the first cavity, the second cavity, and the one or more recesses based at least in part on exhuming the etch stop material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: a substrate; a stack including a first level positioned over the substrate and a second level positioned over the first level, the stack including a memory channel at least partially within the second level, the memory channel including a selector; a plug extending from the first level of the stack to the second level of the stack, the plug contacting the selector; a first conductive material coupled with the plug, the first conductive material having an n-type doping; and a second conductive material coupled with the plug, the second conductive material having a p-type doping, where the plug is positioned between the first conductive material and the second conductive material and extends parallel to the substrate.

Aspect 10: The apparatus of aspect 9, further including: a plurality of memory channels at least partially within the second level, the plurality of memory channels including a plurality of selectors contacting the plug, where: the plurality of memory channels is dispersed along an axis that extends parallel to the substrate; the plug extends under the plurality of memory channels and along the axis within the first level of the stack; and a width of the plug between the first conductive material and the second conductive material is less than a length of the plug along the axis.

Aspect 11: The apparatus of aspect 10, where: the first conductive material extends, parallel to the substrate, along a first sidewall of the plug; and the second conductive material extends, parallel to the substrate, along a second sidewall of the plug, the second sidewall of the plug opposite to the first sidewall of the plug.

Aspect 12: The apparatus of any of aspects 10 through 11, further including: a second plurality of memory channels at least partially within the second level, where the second plurality of memory channels includes a second plurality of selectors; a second plug extending from the first level of the stack to the second level of the stack, the second plug contacting the second plurality of selectors, where the second plug extends along a second axis that is parallel to the axis and the plug; a third conductive material coupled with the second plug, the third conductive material having the n-type doping; a fourth conductive material coupled with the second plug, the fourth conductive material having the p-type doping, where the second plug is positioned between the third conductive material and the fourth conductive material and extends along the second axis parallel to the substrate; and a fifth conductive material positioned between the plug and the second plug, the fifth conductive material having the p-type doping, where the fifth conductive material extends, between the second conductive material having the p-type doping and the third conductive material having the n-type doping, along a third axis that is parallel to the axis and the second axis.

Aspect 13: The apparatus of any of aspects 9 through 12, further including: a plurality of segments of the first conductive material stacked vertically above the substrate and coupled with the plug; a plurality of segments of the second conductive material stacked vertically above the substrate and coupled with the plug, where the plug is positioned between the plurality of segments of the first conductive material and the plurality of segments of the second conductive material; and a source material that at least partially surrounds each segment of the plurality of segments of the first conductive material and each segment of the plurality of segments of the second conductive material.

Aspect 14: The apparatus of any of aspects 9 through 13, further including: a second memory channel at least partially within the second level, where the second memory channel includes a second selector, and where the second memory channel is isolated from the memory channel; a second plug extending from the first level of the stack to the second level of the stack, the second plug contacting the second selector, where the second plug is isolated from the plug; a third conductive material coupled with the second plug, the third conductive material having the n-type doping; and a fourth conductive material coupled with the second plug, the fourth conductive material having the p-type doping, where the second plug is positioned between the third conductive material and the fourth conductive material and extends parallel to the substrate.

Aspect 15: The apparatus of any of aspects 9 through 14, further including: a second memory channel including a second selector contacting the plug, where: the plug extends, along a first axis, vertically from the first level of the stack to the second level of the stack and is positioned between the second selector and the selector of the memory channel in a horizontal direction; the memory channel includes a conductive material that extends, along a second axis, vertically from the plug through at least a portion of the second level of the stack; the second memory channel includes the conductive material that extends, along a third axis, vertically from the plug through at least a portion of the second level of the stack; the first axis extends between the second axis and the third axis; and the first axis, the second axis, and the third axis are parallel.

Aspect 16: The apparatus of any of aspects 9 through 15, where the memory channel includes a cylindrical pillar of conductive material that extends vertically from the plug through at least a portion of the second level.

An apparatus is described. The following provides an overview of aspects of the apparatus as described herein:

Aspect 17: An apparatus, including: a substrate; a stack including a first level positioned over the substrate and a second level positioned over the first level, the stack including a memory channel at least partially within the second level, where the memory channel includes a selector; a plug extending from the first level of the stack to the second level of the stack, the plug contacting the selector; a first conductive material positioned over the substrate and beneath a first portion of the plug, the first conductive material having an n-type doping; and a second conductive material positioned over the substrate and beneath a second portion of the plug, the second conductive material having a p-type doping, where: the plug extends between the first portion and the second portion along an axis parallel to the substrate; and the plug includes a third portion that extends from the substrate to the second level of the stack between the first portion and the second portion of the plug and between the first conductive material and the second conductive material.

Aspect 18: The apparatus of aspect 17, where a width of the plug is the same as a width of the first conductive material and a width of the second conductive material.

Aspect 19: The apparatus of any of aspects 17 through 18, further including: a plurality of memory channels at least partially within the second level, the plurality of memory channels including a plurality of selectors contacting the plug, where: the plurality of memory channels are distributed along the axis that extends parallel to the substrate; and the plug extends under the plurality of memory channels and along the axis within the first level of the stack.

Aspect 20: The apparatus of any of aspects 17 through 19, further including: a second memory channel including a second selector contacting the plug, where: the plug extends, along a first axis, vertically from the first level of the stack to the second level of the stack and is positioned between the second selector and the selector of the memory channel in a horizontal direction; the memory channel includes a conductive material that extends, along a second axis, vertically from the plug through at least a portion of the second level of the stack; the second memory channel includes the conductive material that extends, along a third axis, vertically from the plug through at least a portion of the second level of the stack; the first axis is positioned between the second axis and the third axis; and the first axis, the second axis, and the third axis are parallel.

Aspect 21: The apparatus of any of aspects 17 through 20, where the memory channel includes a cylindrical pillar of conductive material that extends vertically from the plug through at least a portion of the second level.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a substrate;
a stack comprising a first level positioned over the substrate and a second level positioned over the first level, the stack comprising a memory channel at least partially within the second level, the memory channel comprising a selector;
a plug extending from the first level of the stack to the second level of the stack, the plug contacting the selector;
a first conductive material coupled with the plug, the first conductive material having an n-type doping; and
a second conductive material coupled with the plug, the second conductive material having a p-type doping, wherein the plug is positioned between the first conductive material and the second conductive material and extends parallel to the substrate.

2. The apparatus of claim 1, further comprising:
a plurality of memory channels at least partially within the second level, the plurality of memory channels comprising a plurality of selectors contacting the plug, wherein:
the plurality of memory channels is dispersed along an axis that extends parallel to the substrate;
the plug extends under the plurality of memory channels and along the axis within the first level of the stack; and
a width of the plug between the first conductive material and the second conductive material is less than a length of the plug along the axis.

3. The apparatus of claim 2, wherein:
the first conductive material extends, parallel to the substrate, along a first sidewall of the plug; and
the second conductive material extends, parallel to the substrate, along a second sidewall of the plug, the second sidewall of the plug opposite to the first sidewall of the plug.

4. The apparatus of claim 2, further comprising:
a second plurality of memory channels at least partially within the second level, wherein the second plurality of memory channels comprises a second plurality of selectors;
a second plug extending from the first level of the stack to the second level of the stack, the second plug contacting the second plurality of selectors, wherein the second plug extends along a second axis that is parallel to the axis and the plug;
a third conductive material coupled with the second plug, the third conductive material having the n-type doping;
a fourth conductive material coupled with the second plug, the fourth conductive material having the p-type doping, wherein the second plug is positioned between the third conductive material and the fourth conductive material and extends along the second axis parallel to the substrate; and
a fifth conductive material positioned between the plug and the second plug, the fifth conductive material having the p-type doping, wherein the fifth conductive material extends, between the second conductive material having the p-type doping and the third conductive material having the n-type doping, along a third axis that is parallel to the axis and the second axis.

5. The apparatus of claim 1, further comprising:
a plurality of segments of the first conductive material stacked vertically above the substrate and coupled with the plug;
a plurality of segments of the second conductive material stacked vertically above the substrate and coupled with the plug, wherein the plug is positioned between the plurality of segments of the first conductive material and the plurality of segments of the second conductive material; and
a source material that at least partially surrounds each segment of the plurality of segments of the first conductive material and each segment of the plurality of segments of the second conductive material.

6. The apparatus of claim 1, further comprising:
a second memory channel at least partially within the second level, wherein the second memory channel comprises a second selector, and wherein the second memory channel is isolated from the memory channel;
a second plug extending from the first level of the stack to the second level of the stack, the second plug contacting the second selector, wherein the second plug is isolated from the plug;
a third conductive material coupled with the second plug, the third conductive material having the n-type doping; and
a fourth conductive material coupled with the second plug, the fourth conductive material having the p-type doping, wherein the second plug is positioned between the third conductive material and the fourth conductive material and extends parallel to the substrate.

7. The apparatus of claim 1, further comprising:
a second memory channel comprising a second selector contacting the plug, wherein:
the plug extends, along a first axis, vertically from the first level of the stack to the second level of the stack and is positioned between the second selector and the selector of the memory channel in a horizontal direction;
the memory channel comprises a conductive material that extends, along a second axis, vertically from the plug through at least a portion of the second level of the stack;
the second memory channel comprises the conductive material that extends, along a third axis, vertically from the plug through at least a portion of the second level of the stack;
the first axis extends between the second axis and the third axis; and
the first axis, the second axis, and the third axis are parallel.

8. The apparatus of claim 1, wherein the memory channel comprises a cylindrical pillar of conductive material that extends vertically from the plug through at least a portion of the second level.

9. An apparatus, comprising:
a substrate;
a stack comprising a first level positioned over the substrate and a second level positioned over the first level, the stack comprising a memory channel at least partially within the second level, wherein the memory channel comprises a selector;
a plug extending from the first level of the stack to the second level of the stack, the plug contacting the selector;
a first conductive material positioned over the substrate and beneath a first portion of the plug, the first conductive material having an n-type doping; and
a second conductive material positioned over the substrate and beneath a second portion of the plug, the second conductive material having a p-type doping, wherein:
the plug extends between the first portion and the second portion along an axis parallel to the substrate; and
the plug comprises a third portion that extends from the substrate to the second level of the stack between the first portion and the second portion of the plug and between the first conductive material and the second conductive material.

10. The apparatus of claim 9, wherein a width of the plug is the same as a width of the first conductive material and a width of the second conductive material.

11. The apparatus of claim 9, further comprising:
a plurality of memory channels at least partially within the second level, the plurality of memory channels comprising a plurality of selectors contacting the plug, wherein:
the plurality of memory channels are distributed along the axis that extends parallel to the substrate; and
the plug extends under the plurality of memory channels and along the axis within the first level of the stack.

12. The apparatus of claim 9, further comprising:
a second memory channel comprising a second selector contacting the plug, wherein:
the plug extends, along a first axis, vertically from the first level of the stack to the second level of the stack and is positioned between the second selector and the selector of the memory channel in a horizontal direction;
the memory channel comprises a conductive material that extends, along a second axis, vertically from the plug through at least a portion of the second level of the stack;
the second memory channel comprises the conductive material that extends, along a third axis, vertically from the plug through at least a portion of the second level of the stack;
the first axis is positioned between the second axis and the third axis; and
the first axis, the second axis, and the third axis are parallel.

13. The apparatus of claim 9, wherein the memory channel comprises a cylindrical pillar of conductive material that extends vertically from the plug through at least a portion of the second level.

14. A method, comprising:
forming a stack comprising a plurality of oxide layers and a plurality of sacrificial material layers within a first level positioned over a substrate and within a second level positioned over the first level;
forming a storage material and a conductive material within at least a portion of the first level to form a plug;
forming the storage material and the conductive material within at least a portion of the second level to form one or more memory channels coupled with the plug;
etching the first level of the stack to expose one or more sidewalls of the plug;
forming a masking material to contact at least a portion of the one or more sidewalls of the plug;
performing, based at least in part on the masking material, a first directional doping operation on a first exposed portion of the plug to dope a first portion of the conductive material with an n-type dopant; and
performing, based at least in part on the masking material, a second directional doping operation on a second exposed portion of the plug to dope a second portion of the conductive material with a p-type dopant, wherein the first portion of the conductive material is separated from the second portion of the conductive material by a portion of the plug.

15. The method of claim 14, wherein forming the masking material comprises:
forming the masking material along the one or more sidewalls of the portion of the plug, wherein the first portion of the conductive material and the second portion of the conductive material extend horizontally from opposite sides of the portion of the plug, and wherein performing the first directional doping operation comprises:
doping the first portion of the conductive material with the n-type dopant directed to a first side of the plug, wherein the masking material coupled with the portion of the plug blocks the second portion of the conductive material on a second side of the plug from the n-type dopant; and
wherein performing the second directional doping operation comprises:
doping the second portion of the conductive material with the p-type dopant, wherein the masking material coupled with the portion of the plug blocks the first portion of the conductive material on the first side of the plug from the p-type dopant.

16. The method of claim 14, further comprising:
forming the masking material between the substrate and the second exposed portion of the plug, wherein the first directional doping operation dopes the first portion of the conductive material in the first exposed portion of the plug based at least in part on forming the masking material between the substrate and the second exposed portion of the plug;
removing, after performing the first directional doping operation, the masking material; and
forming the masking material between the substrate and the first exposed portion of the plug after removing the masking material, wherein the second directional doping operation dopes the second portion of the conductive material in the second exposed portion of the plug based at least in part on forming the masking material between the substrate and the first exposed portion of the plug.

17. The method of claim 14, wherein forming the masking material comprises:
forming an anisotropic material to contact the one or more sidewalls of the plug, wherein the first directional doping operation and the second directional doping operation are based at least in part on the anisotropic material.

18. The method of claim 14, further comprising:
removing the masking material and the storage material after performing the first directional doping operation and the second directional doping operation; and
forming, after removing the masking material and the storage material, a source that at least partially surrounds the plug, the first portion of the conductive material, and the second portion of the conductive material.

19. The method of claim 14, further comprising:
rotating, after forming the conductive material, the stack to expose a bottom surface of the first level of the stack, wherein etching the first level of the stack to expose the one or more sidewalls of the plug is based at least in part on rotating the stack; and
performing, after forming the conductive material, a replacement gate procedure to replace the plurality of sacrificial material layers with one or more metal layers.

20. The method of claim 14, wherein the n-type dopant comprises phosphorous and the p-type dopant comprises boron.

21. The method of claim 14, further comprising:
etching the first level of the stack to form a first cavity that extends vertically through at least a portion of the first level of the stack;
etching, via the first cavity, a first layer of the plurality of sacrificial material layers to form one or more recesses that extend within the first layer from the first cavity;
forming an etch stop material in the first cavity and the one or more recesses;
forming the second level of the stack above the first level of the stack and the etch stop material;
etching the second level of the stack to form a second cavity that extends vertically to the etch stop material in the first level of the stack; and
exhuming, via the second cavity, the etch stop material, wherein forming the conductive material comprises forming the conductive material within the first cavity, the second cavity, and the one or more recesses based at least in part on exhuming the etch stop material.
